(19) United States
(12) Patent Application Publication
(10) Pub. No.: US 2025/0028298 A1
(43) Pub. Date: Jan. 23, 2025

(54) THERMAL CONTROL SYSTEMS, MODELS, AND MANUFACTURING PROCESSES IN LITHOGRAPHY

(71) Applicant: ASML NETHERLANDS B.V., Veldhoven (NL)

(72) Inventors: Duan-Fu Stephen HSU, Fremont, CA (US); Gerui LIU, San Jose, CA (US); Wenjie JIN, Eindhoven (NL); Dezheng SUN, Palo Alto, CA (US)

(73) Assignee: ASML NETHERLANDS B.V., Veldhoven (NL)

(21) Appl. No.: 18/713,127

(22) PCT Filed: Nov. 30, 2022
(86) PCT No.: PCT/EP2022/083818

§ 371 Date: May 23, 2024

Related U.S. Application Data
(60) Provisional application No. 63/289,591, filed on Dec. 14, 2021.

(51) Int. Cl. G05B 19/4093

(52) U.S. Cl. CPC G05B 19/40931; G05B 2219/45028; G05B 2219/45031

(57) ABSTRACT

Dynamic aberration control in a semiconductor manufacturing process is described. In some embodiments, wavefront data representing a wavefront provided by an optical projection system of a semiconductor processing apparatus may be received. Wavefront drift may be determined based on a comparison of the wavefront data and target wavefront data. Based on the wavefront drift, one or more process parameters may be determined. The one or more process parameters include parameters associated with a thermal device, where the thermal device is configured to provide thermal energy to the optical projection system during operation.

### CROSS-REFERENCE TO RELATED APPLICATIONS

This application claims priority of U.S. application 63/289,591 which was filed on Dec. 14, 2021 and which is incorporated herein in its entirety by reference.

### TECHNICAL FIELD

The description herein relates generally to lithography in semiconductor manufacturing, and more particularly, to computational lithography.

### BACKGROUND

A lithographic projection apparatus can be used, for example, in the manufacture of integrated circuits (ICs). A patterning device (e.g., a mask) may include or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices can be found in, for example, U.S. Pat. No. 6,046,792, incorporated herein by reference in its entirety.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish the individual layer of the device. If several layers are required in the device, then the whole procedure, or a variant thereof, is repeated for each layer. Eventually, a device will be present in each target portion on the substrate. These devices are then separated from one another by a technique such as dicing or sawing, such that the individual devices can be mounted on a carrier, connected to pins, etc.

Manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

Lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced. At the same time, the number of functional elements, such as transistors, per device has been steadily increasing, following a trend commonly referred to as “Moore's law.” At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is commonly known as low-k1 lithography, according to the resolution formula CD=k1×λ/NA, where 2 is the wavelength of radiation employed (currently in most cases 248 nm or 193 nm), NA is the numerical aperture of projection optics in the lithographic projection apparatus, CD is the “critical dimension”—generally the smallest feature size printed—and k1 is an empirical resolution factor. In general, the smaller k1 the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET).

OPC and other RET utilize robust electronic models that describe the lithography process. Calibration procedures for such lithography models are thus desired that provide valid, robust and accurate models across the process window. Currently, calibration is done using a certain number of 1-dimensional and/or 2-dimensional gauge patterns with wafer measurements. More specifically, the 1-dimensional gauge patterns include line-space patterns with a varying pitch and critical dimension (CD), isolated lines, multiple lines, etc. The 2-dimensional gauge patterns typically include line-ends, contacts, and randomly selected SRAM (Static Random Access Memory) patterns.

### SUMMARY

It is desirable to reduce or otherwise control aberration drift so as to reduce defects when manufacturing devices, such as semiconductor devices, using the lithography process. One cause of aberrations drift, is undesired or unexpected thermal changes to one or more components of the optical projection system. For example, as light (e.g., EUV light, DUV light) is incident on various optical elements of the optical projection system, those optical elements may “heat” up. The “heating” of the optical elements may cause the optical elements to deform, which results in changes to a wavefront provided by the optical projection system for patterning devices.

According to some embodiments, there is a method for determining one or more process parameters. The method includes obtaining a wavefront drift of a wavefront provided by an optical projection system of a semiconductor processing apparatus. The wavefront drift may be determined based on a comparison of wavefront data representing the wavefront and target wavefront data. The method may further include determining the one or more process parameters based on the wavefront drift. The one or more process parameters may include parameters associated with a thermal device, where the thermal device may be configured to provide thermal energy (e.g., provide external heating or external cooling) to the optical projection system during operation.

According to some embodiments, there is a non-transitory computer-readable medium storing computer program instructions that, when executed by one or more processors, effectuates operations including any of the methods described above.

According to some embodiments, there is a semiconductor processing apparatus including the optical projection system and the one or more thermal device, and wherein any of the methods described above may be executed using the semiconductor processing apparatus.

### BRIEF DESCRIPTION OF THE DRAWINGS

The accompanying drawings, which are incorporated in and constitute a part of the specification, illustrate one or more embodiments and, together with the description, explain these embodiments. Embodiments of the invention will now be described, by way of example only, with reference to the accompanying schematic drawings in which corresponding reference symbols indicate corresponding parts, and in which:

FIG. 1 illustrates a block diagram of various subsystems of a lithographic projection apparatus, according to an embodiment of the present disclosure.

FIG. 2 illustrates an exemplary flowchart for fully simulating lithography in a lithographic projection apparatus, according to an embodiment of the present disclosure.

FIG. 3 illustrates dynamic aberration correction based on semiconductor processing metrics per-substrate (e.g., per wafer or even per layer), according to an embodiment of the present disclosure.

FIG. 4A illustrates an exemplary flowchart for determining process parameters associated with a thermal device, according to an embodiment of the present disclosure.

FIG. 4B illustrates another exemplary flowchart for determining process parameters associated with a thermal device, according to an embodiment of the present disclosure.

FIG. 5 illustrates an example optical projection system including optical elements, according to an embodiment of the present disclosure.

FIGS. 6A and 6B illustrate an example heating state of an example optical element of an optical projection system, and an optical element deformation map, respectively, according to an embodiment of the present disclosure.

FIG. 7 illustrates an example optical element and adjustments capable of being made to a configuration of the optical element, according to an embodiment of the present disclosure.

FIG. 8 illustrates an optical element and a set of thermal devices providing thermal energy to the optical element, according to an embodiment of the present disclosure.

FIG. 9 illustrates an example optical projection system including optical elements, thermal devices used to provide thermal energy to some or all of the optical elements, and control devices for controlling an orientation of some or all of the optical elements, according to an embodiment of the present disclosure.

FIGS. 10A and 10B illustrate example methods for performing offline and online thermal correction for one or more optical elements of an optical projection system, according to an embodiment of the present disclosure.

FIG. 11 is a schematic diagram of a lithographic projection apparatus, according to an embodiment of the present disclosure.

FIG. 12 is a schematic diagram of another lithographic projection apparatus, according to an embodiment of the present disclosure.

FIG. 13 is a detailed view of a lithographic projection apparatus, according to an embodiment of the present disclosure.

FIG. 14 is a detailed view of the source collector module of the lithographic projection apparatus, according to an embodiment of the present disclosure.

FIG. 15 is a block diagram of an example computer system, according to an embodiment of the present disclosure.

### DETAILED DESCRIPTION

Being able to control or correct for wavefront drift induced by optical heating in semiconductor manufacturing processes is advantageous. For example, by correcting for wavefront drift in a lithography system, where the wavefront drift is induced by the heating of optical elements of the lithography system (e.g., mirrors, lenses, etc.), defects in devices fabricated via one or more of the semiconductor manufacturing processes may be significantly reduced.

In lithography systems, mirror heating, lens heating, and/or other dynamically changing factors to the production of patterned devices, such as semiconductor devices, can cause defects (e.g., edge placement errors, overlay errors, etc.). This demands fast and precise in-situ correction capabilities to achieve stable imaging performance in production manufacturing environments. For example, mirror heating can cause wavefront drift, which is when a wavefront provided by an optical projection system of the lithography system differs from a target wavefront to be provided by the optical projection system.

One prior attempt at this fast in-situ control included definition of a merit function based on pupil level properties (e.g., RMS of a delta wave front with respect to a reference state) of a scanner, but was unaware of the imaging performance properties on a substrate (e.g., wafer) level. As a consequence, although aberrations on the pupil level were minimized, the imaging performance (on the substrate or wafer level) was not optimized.

An alternative imaging performance based approach includes calculation of the Zernike sensitivities of vast numbers of critical dimensions. Using this approach, lithography performance metrics are limited to critical dimensions. This approach is not flexible enough to cover other types of custom metrics including discrete metrics (e.g. defect counts, etc.). A different approach involves a method for matching the performance of different scanners by performing aberration (wave front) optimization using a source mask optimization engine. However, this approach was designed for a cold lens setup without considering mirror heating and it performs an iterative optimization, which requires a full imaging simulation for every iteration. This is computationally heavy and unsuitable for dynamic in-situ scanner control. Still another different approach uses a calibrated aberration impact model configured to receive patterning system aberration data and determine new patterning process impact data for the received patterning system aberration data. However, this approach is no longer sufficient due to the limited amount of rigid body mirror movements in the projection optics box (POB) of the driver lens model (DLM) to apply wavefront correction to mitigate the mirror heating impact for EUV scanners, which operate at high source power.

Embodiments of the present application are described in detail with reference to the drawings, which are provided as illustrative examples of the disclosure so as to enable those skilled in the art to practice the disclosure. Notably, the figures and examples below are not meant to limit the scope of the present disclosure to a single embodiment, but other embodiments are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure. Embodiments described as being implemented in software should not be limited thereto, but can include embodiments implemented in hardware, or combinations of software and hardware, and vice-versa, as will be apparent to those skilled in the art, unless otherwise specified herein. In the present specification, an embodiment showing a singular component should not be considered limiting; rather, the disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present disclosure encompasses present and future known equivalents to the known components referred to herein by way of illustration.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “projection optics,” as used herein, should be broadly interpreted as encompassing various types of optical systems and subsystems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the (e.g., semiconductor) patterning device, and/or optical components for shaping, adjusting and/or projecting the radiation after the radiation passes the patterning device. The projection optics generally exclude the source and the patterning device.

The (e.g., semiconductor) patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. The design rules may include and/or specify specific parameters, limits on and/or ranges for parameters, and/or other information. One or more of the design rule limitations and/or parameters may be referred to as a “critical dimension” (CD). A critical dimension of a device can be defined as the smallest width of a line or hole or the smallest space between two lines or two holes, or other features. Thus, the CD determines the overall size and density of the designed device. One of the goals in device fabrication is to faithfully reproduce the original design intent on the substrate (via the patterning device).

The term “mask” or “patterning device” as employed in this text may be broadly interpreted as referring to a generic semiconductor patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include a programmable mirror array and a programmable LCD array.

An example of a programmable mirror array can be a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means. An example of a programmable LCD array is given in U.S. Pat. No. 5,229,872, which is incorporated herein by reference.

As used herein, the term “patterning process” generally means a process that creates an etched substrate by the application of specified patterns of light as part of a lithography process. However, “patterning process” can also include plasma etching, as many of the features described herein can provide benefits to forming printed patterns using plasma processing.

As used herein, the term “target pattern” means an idealized pattern that is to be etched on a substrate.

As used herein, the term “printed pattern” means the physical pattern on a substrate that was etched based on a target pattern. The printed pattern can include, for example, troughs, channels, depressions, edges, or other two and three dimensional features resulting from a lithography process.

As used herein, the term “prediction model,” “process model,” and/or model (which may be used interchangeably) means a model that includes one or more models that simulate a patterning process. For example, a prediction and/or process model can include an optical model (e.g., that models a lens system/projection system used to deliver light in a lithography process and may include modelling the final optical image of light that goes onto a photoresist), a resist model (e.g., that models physical effects of the resist, such as chemical effects due to the light), and/or an OPC model (e.g., that can be used to make target patterns and may include sub-resolution resist features (SRAFs), etc.), and/or other models.

As used herein, the term “calibrating” means to modify (e.g., improve or tune) and/or validate something, such as the process model.

A patterning system may be a system comprising any or all of the components described above, plus other components configured to performing any or all of the operations associated with these components. A patterning system may include a lithographic projection apparatus, a scanner, and/or other systems, for example.

A lithographic projection apparatus may be a device including any or all of the components described above. In some embodiments, a lithographic projection apparatus may be referred to herein interchangeably as a semiconductor processing apparatus.

A thermal device, as described herein, refers to a device that provides, or facilitates the providing of, thermal energy to an object. The thermal energy may cause “heating” (e.g., raising of a temperature), “cooling” (e.g., lowering of a temperature), or may cause no change in temperature. The thermal device can be implemented in any suitable configuration, heating or cooling mechanism, control mechanism without departing from the scope of the present disclosure.

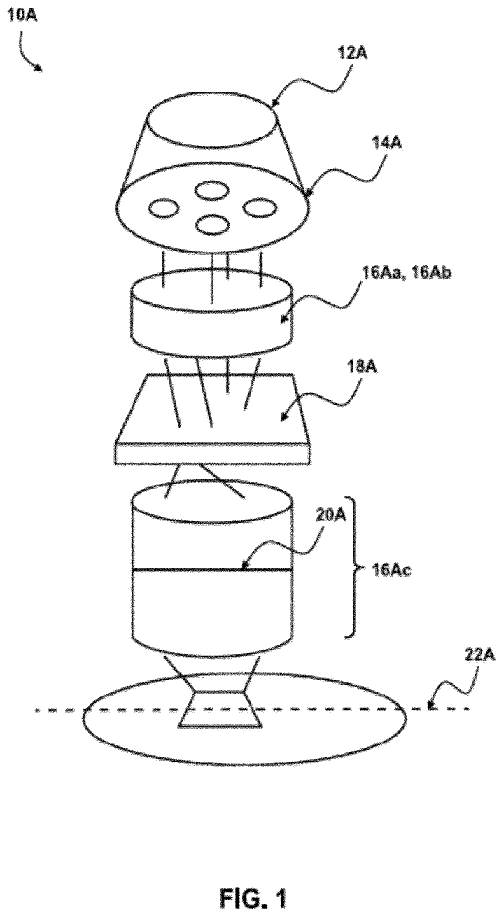

As an introduction, FIG. 1 illustrates a diagram of various subsystems of an example lithographic projection apparatus 10A. Lithographic projection apparatus 10A includes various components, such as a radiation source 12A, which may be a deep-ultraviolet excimer laser source or other type of source including an extreme ultra violet (EUV) source (as discussed above, the lithographic projection apparatus itself need not have the radiation source), illumination optics which, for example, define the partial coherence (denoted as sigma) and which may include optics 14A, 16Aa and 16Ab that shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin (Θₘₐₓ), wherein n is the refractive index of the media between the substrate and the last element of the projection optics, and Θₘₐₓ is the largest angle of the beam exiting from the projection optics that can still impinge on the substrate plane 22A.

In a lithographic projection apparatus, a source provides illumination (i.e. radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist model can be used to calculate the resist image from the aerial image, an example of which can be found in U.S. Patent Application Publication No. US 2009-0157630, the disclosure of which is hereby incorporated by reference in its entirety. The resist model is related to properties of the resist layer (e.g., effects of chemical processes which occur during exposure, post-exposure bake (PEB) and development). Optical properties of the lithographic projection apparatus (e.g., properties of the illumination, the patterning device and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each which is hereby incorporated by reference in its entirety.

It may be desirable to use one or more tools to produce results that, for example, can be used to design, control, monitor, etc. the patterning process. One or more tools used in computationally controlling, designing, etc. one or more aspects of the patterning process, such as the pattern design for a patterning device (including, for example, adding sub-resolution assist features or optical proximity corrections), the illumination for the patterning device, etc., may be provided. Accordingly, in a system for computationally controlling, designing, etc. a manufacturing process involving patterning, the manufacturing system components and/or processes can be described by various functional modules and/or models. In some embodiments, one or more electronic (e.g., mathematical, parameterized, etc.) models may be provided that describe one or more steps and/or apparatuses of the patterning process. In some embodiments, a simulation of the patterning process can be performed using one or more electronic models to simulate how the patterning process forms a patterned substrate using a design pattern provided by a patterning device.

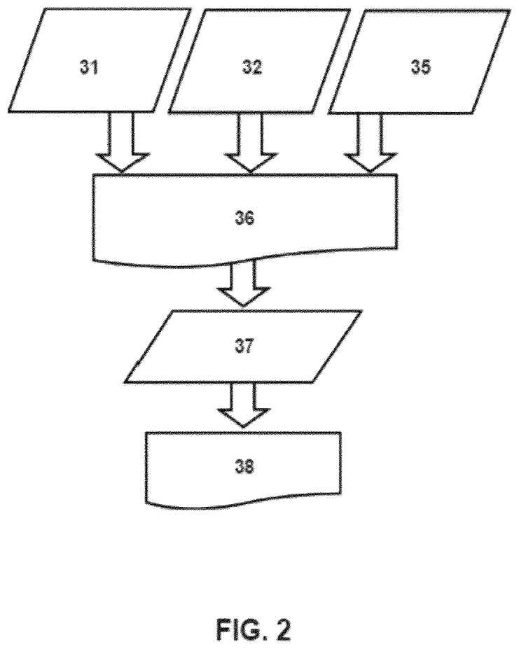

An exemplary flow chart for simulating lithography in a lithographic projection apparatus is illustrated in FIG. 2. This may be an exemplary full lithography simulation. An illumination model 31 represents optical characteristics (including radiation intensity distribution and/or phase distribution) of the illumination. A projection optics model 32 represents optical characteristics (including changes to the radiation intensity distribution and/or the phase distribution caused by the projection optics) of the projection optics. A design layout model 35 represents optical characteristics (including changes to the radiation intensity distribution and/or the phase distribution caused by a given design layout) of a design layout, which is the representation of an arrangement of features on or formed by a patterning device. An aerial image 36 can be simulated using the illumination model 31, the projection optics model 32, and the design layout model 35. A resist image 38 can be simulated from the aerial image 36 using a resist model 37. Simulation of lithography can, for example, predict contours and/or CDs in the resist image.

More specifically, illumination model 31 can represent the optical characteristics of the illumination that include, but are not limited to, NA-sigma (o) settings as well as any particular illumination shape (e.g. off-axis illumination such as annular, quadrupole, dipole, etc.). The projection optics model 32 can represent the optical characteristics of the of the projection optics, including, for example, aberration, distortion, a refractive index, a physical size or dimension, etc. The design layout model 35 can also represent one or more physical properties of a physical patterning device, as described, for example, in U.S. Pat. No. 7,587,704, which is incorporated by reference in its entirety. Optical properties associated with the lithographic projection apparatus (e.g., properties of the illumination, the patterning device and the projection optics) dictate the aerial image. Since the patterning device used in the lithographic projection apparatus can be changed, it is desirable to separate the optical properties of the patterning device from the optical properties of the rest of the lithographic projection apparatus including at least the illumination and the projection optics (hence design layout model 35).

The resist model 37 can be used to calculate the resist image from the aerial image, an example of which can be found in U.S. Pat. No. 8,200,468, which is hereby incorporated by reference in its entirety. The resist model is typically related to properties of the resist layer (e.g., effects of chemical processes which occur during exposure, post-exposure bake and/or development).

One of the objectives of the full simulation is to accurately predict, for example, edge placements, aerial image intensity slopes and/or CDs, which can then be compared against an intended design. The intended design is generally defined as a pre-OPC design layout which can be provided in a standardized digital file format such as GDS, GDSII, OASIS, or other file formats.

From the design layout, one or more portions may be identified, which are referred to as “clips.” In an embodiment, a set of clips is extracted, which represents the complicated patterns in the design layout (typically about 50 to 1000 clips, although any number of clips may be used). As will be appreciated by those skilled in the art, these patterns or clips represent small portions (e.g., circuits, cells, etc.) of the design and especially the clips represent small portions for which particular attention and/or verification is needed. In other words, clips may be the portions of the design layout or may be similar or have a similar behavior of portions of the design layout where critical features are identified either by experience (including clips provided by a customer), by trial and error, or by running a full-chip simulation. Clips often contain one or more test patterns or gauge patterns. An initial larger set of clips may be provided a priori by a customer based on known critical feature areas in a design layout which require particular image optimization. Alternatively, in another embodiment, the initial larger set of clips may be extracted from the entire design layout by using an automated (such as, machine vision) or manual algorithm that identifies the critical feature areas.

For example, the simulation and modeling can be used to configure one or more features of the patterning device pattern (e.g., performing optical proximity correction), one or more features of the illumination (e.g., changing one or more characteristics of a spatial/angular intensity distribution of the illumination, such as change a shape), and/or one or more features of the projection optics (e.g., numerical aperture, etc.). Such configuration can be generally referred to as, respectively, mask optimization, source optimization, and projection optimization. Such optimization can be performed on their own, or combined in different combinations. One such example is source-mask optimization (SMO), which involves the configuring of one or more features of the patterning device pattern together with one or more features of the illumination. The optimization techniques may focus on one or more of the clips. The optimizations may use the machine learning model described herein to predict values of various parameters (including images, etc.).

In some embodiments, an optimization process of a system may be represented as a cost function. The optimization process may including determining process parameters (e.g., operational settings of a thermal device) of the system that minimizes the cost function. The cost function can have any suitable form depending on the goal of the optimization. For example, the cost function can be weighted root mean square (RMS) of deviations of certain characteristics (evaluation points) of the system with respect to the intended values (e.g., ideal values) of these characteristics. The cost function can also be the maximum of these deviations (i.e., worst deviation). The term “evaluation points” should be interpreted broadly to include any characteristics of the system or fabrication method. The design and/or process variables of the system can be confined to finite ranges and/or be interdependent due to practicalities of implementations of the system and/or method. In the case of a lithographic projection apparatus, the constraints are often associated with physical properties and characteristics of the hardware such as tunable ranges, and/or patterning device manufacturability design rules. The evaluation points can include physical points on a resist image on a substrate, as well as non-physical characteristics such as dose and focus, for example.

In a lithographic projection apparatus, as an example, a cost function may be expressed as

$$CF ( {z}_{1} , {z}_{2} , … , {z}_{N} ) = {\sum }_{p = 1}^{P} {w}_{p} {f}_{p}^{2} ( {z}_{1} , {z}_{2} , … , {z}_{N} ) , \qquad Equation 1$$

where (Z₁, Z₂, . . . , Z_{N}) are N design variables or values thereof, and fₚ(Z₁, Z₂, . . . , Z_{N}) can be a function of the design variables (Z₁, Z₂, . . . , Z_{N}) such as a difference between an actual value and an intended value of a characteristic for a set of values of the design variables of (Z₁, Z₂, . . . , Z_{N}). In some embodiments, wₚ is a weight constant associated with fₚ(Z₁, Z₂, . . . , Z_{N}). For example, the characteristic may be a position of an edge of a pattern, measured at a given point on the edge. Different fₚ(Z₁, Z₂, . . . , Z_{N}) may have different weight wₚ. For example, if a particular edge has a narrow range of permitted positions, the weight wₚ for the fₚ(Z₁, Z₂, . . . , Z_{N}) representing the difference between the actual position and the intended position of the edge may be given a higher value. fₚ(Z₁, Z₂, . . . , Z_{N}) can also be a function of an interlayer characteristic, which is in turn a function of the design variables (Z₁, Z₂, . . . , Z_{N}). Of course, CF(Z₁, Z₂, . . . , Z_{N}) is not limited to the form in the equation above and CF(Z₁, Z₂, . . . , Z_{N}) can be in any other suitable form.

The cost function may represent any one or more suitable characteristics of the lithographic projection apparatus, lithographic process or the substrate, for instance, focus, CD, image shift, image distortion, image rotation, stochastic variation, throughput, local CD variation, process window, an interlayer characteristic, or a combination thereof. In some embodiments, the cost function may include a function that represents one or more characteristics of the resist image. For example, fₚ(Z₁, Z₂, . . . , Z_{N}) can be simply a distance between a point in the resist image to an intended position of that point (i.e., edge placement error EPEₚ(Z₁, Z₂, . . . , Z_{N}). The parameters (e.g., design variables) can include any adjustable parameter such as an adjustable parameter of the source, the patterning device, the projection optics, dose, focus, etc.

The parameters (e.g., design variables) may have constraints, which can be expressed as (Z₁, Z₂, . . . , Z_{N})∈Z, where Z is a set of possible values of the design variables. One possible constraint on the design variables may be imposed by a desired throughput of the lithographic projection apparatus. Without such a constraint imposed by the desired throughput, the optimization may yield a set of values of the design variables that are unrealistic. Constraints should not be interpreted as a necessity. For example, the throughput may be affected by the pupil fill ratio. For some illumination designs, a low pupil fill ratio may discard radiation, leading to lower throughput. Throughput may also be affected by the resist chemistry. Slower resist (e.g., a resist that requires higher amount of radiation to be properly exposed) leads to lower throughput.

In some embodiments, illumination model 31, projection optics model 32, design layout model 35, resist model 37, and/or other models associated with and/or included in an integrated circuit manufacturing process may be an empirical model that performs the operations of the method described herein. The empirical model may predict outputs based on correlations between various inputs (e.g., one or more characteristics of a mask or wafer image, one or more characteristics of a design layout, one or more characteristics of the patterning device, one or more characteristics of the illumination used in the lithographic process such as the wavelength, etc.).

As an example, the empirical model may comprise one or more algorithms. As another example, the empirical model may be a machine learning model and/or any other parameterized model. In some embodiments, the machine learning model (for example) may be and/or include mathematical equations, algorithms, plots, charts, networks (e.g., neural networks), and/or other tools and machine learning model components. For example, the machine learning model may be and/or include one or more neural networks having an input layer, an output layer, and one or more intermediate or hidden layers. In some embodiments, the one or more neural networks may be and/or include deep neural networks (e.g., neural networks that have one or more intermediate or hidden layers between the input and output layers).

As an example, the one or more neural networks may be based on a large collection of neural units (or artificial neurons). The one or more neural networks may loosely mimic the manner in which a biological brain works (e.g., via large clusters of biological neurons connected by axons). Each neural unit of a neural network may be connected with many other neural units of the neural network. Such connections can be enforcing or inhibitory in their effect on the activation state of connected neural units. In some embodiments, each individual neural unit may have a summation function that combines the values of all its inputs together. In some embodiments, each connection (or the neural unit itself) may have a threshold function such that a signal must surpass the threshold before it is allowed to propagate to other neural units. These neural network systems may be self-learning and trained, rather than explicitly programmed, and can perform significantly better in certain areas of problem solving, as compared to traditional computer programs. In some embodiments, the one or more neural networks may include multiple layers (e.g., where a signal path traverses from front layers to back layers). In some embodiments, back propagation techniques may be utilized by the neural networks, where forward stimulation is used to reset weights on the “front” neural units. In some embodiments, stimulation and inhibition for the one or more neural networks may be freer flowing, with connections interacting in a more chaotic and complex fashion. In some embodiments, the intermediate layers of the one or more neural networks include one or more convolutional layers, one or more recurrent layers, and/or other layers.

The one or more neural networks may be trained (i.e., whose parameters are determined) using a set of training information. The training information may include a set of training samples. Each sample may be a pair comprising an input object (typically a vector, which may be called a feature vector) and a desired output value (also called the supervisory signal). A training algorithm analyzes the training information and adjusts the behavior of the neural network by adjusting the parameters (e.g., weights of one or more layers) of the neural network based on the training information. For example, given a set of N training samples of the form {(x₁, y₁), (x₂, y₂), . . . , (x_{N}, y_{N})} such that xᵢ is the feature vector of the i-th example and yᵢ is its supervisory signal, a training algorithm seeks a neural network g: X→Y, where X is the input space and Y is the output space. A feature vector is an n-dimensional vector of numerical features that represent some object (e.g., a simulated aerial image, a wafer design, a clip, etc.). The vector space associated with these vectors is often called the feature space. After training, the neural network may be used for making predictions using new samples.

It is desirable to reduce a quantity of patterned devices having defects as well as a magnitude (e.g., a size) of the defects. One cause of such defects is undesired or unexpected thermal changes to one or more components of the optical projection system of the lithography system. For example, as light (e.g., EUV light, DUV light) is incident on various optical elements of the optical projection system, those optical elements may “heat” up. The “heating” of the optical elements may cause the optical elements to deform, which results in unexpected changes to a wavefront provided by the optical projection system for patterning devices, referred to as wavefront drift. Some previous solutions corrected for wavefront drift by adjusting a configuration of the optical projection system. However, the amount that each optical element can be adjusted is limited and as the energy level (e.g., EUV light) increases, adjustments to the orientation of the optical elements may not be enough to mitigate the wavefront drift.

In some embodiments, there is provided a method for determining one or more process parameters to mitigate the heating effect from the optical elements in lithography process. According to embodiments of the present disclosure, the present systems and methods determine an amount of thermal energy to be provided to one or more sections of one or more optical elements of an optical projection system, as well an adjustment to a configuration of the one or more optical elements based on imaging performance characteristics. In some embodiments, the optimization includes adjusting the thermal device configuration in response to wavefront drift, optionally along with other tunable parameters in the lithography system (e.g., optical elements). In some embodiments, the optimization may aim to reduce cost in terms of wavefront aberration, e.g., to minimize or otherwise reduced wavefront aberration or to converge to a target wavefront. In some embodiments, the optimization aims to minimize or otherwise reduce an edge placement error (EPE) cost or other semiconductor patterning process metrics. Although embodiments of the present disclosure are described in details by referencing to “minimize” a cost function, it will be appreciated that any other optimization mechanisms with respect to a cost function can be used without departing from the scope of the present disclosure. The optimization can be performed in a modeling or simulation process. In some embodiments, the optimization includes minimizing the EPE cost may include minimizing a cost function. The cost function may, for example, be represented as

$$EPE Cost = {min}_{δ , SH} {\vert L [ WFM ( {HS}_{illumination} + {HS}_{SH} ) + {WVF}_{D δ} - {WVF}_{Target} ] \vert}^{2} , \qquad Equation 2$$

where L represents one or more semiconductor processing metrics (e.g., lithography metrics, also referred to herein interchangeably as “lithometric”), and may be determined based on light output by an illumination source (e.g., an EUV light source) and a layout of the patterning device, projection optics (e.g., optical elements of a projection optics system), and or other components of the lithography apparatus. Semiconductor processing metrics L may function as a weight to the terms in the brackets. Additional details regarding semiconductor processing metrics Z is provided below with respect to Equations 6 and 7. The term WFM represents a wavefront model, which is configured to generate a simulation of a wavefront provided by the optical projection system. In some embodiments, a wavefront sensor may be used to detect the wavefront provided by the optical projection system. In some embodiments, multiple wavefront sensors may be used to detect the wavefront at various points along the optical path. The wavefront model WFM may compute the wavefront based on a heating state of some or all of the optical elements included in the optical projection system. In some other embodiments, the cost function may not be configured to calculate semiconductor processing metrics but comprises terms representing wavefront aberration. By using such a cost function, the optimization iterations may aim to reduce RMS of wavefront aberration, or converge to a target wavefront.

In some embodiments, an illumination source, such as an EUV light source may incident some or all of the optical elements included in the optical projection system. Light sources outputting light of any other wavelength or set of wavelengths, such as, for example, DUV light, may be used instead of an EUV light source. The illumination may cause the optical elements to heat up. As a result, the light that incidents the wafer (e.g., after being incident on the mask and subsequently the optical elements of the optical projection system) to form a particular pattern may differ from that which is expected, resulting in the creation of defects to the end product. According to embodiments of the present disclosure, the heating state of the optical elements, including the thermal influence from the thermal device configured to compensate for the heating impact, may be taken into consideration and simulated or modeled using a thermal model that takes, as input, properties of the light output by the illumination source, configurations of the optical projection systems, or other settings of the semiconductor processing apparatus, and generates a simulated wavefront as a function of time. This simulated wavefront is based on heating of the optical elements.

A technical effect of the techniques described herein may be improved imaging performance. For instance, reducing aberrations during the patterning processes can improve the imaging performance. To reduce aberration or control aberration in a more deterministic manner, the effects of thermal energy to the wafer patterning process (e.g., deformation of optical elements due to thermal changes) may be mitigated. One technique to mitigate the effects of thermal energy, for example, is by adjusting a configuration of the optical projection system. In some embodiments, adjusting the configuration of the optical projection system may include adjusting an orientation of one or more optical elements of the optical projection system. The orientation of an optical element can affect a heating state of the optical element. For example, adjusting the optical element's orientation can cause the heating state produced by the optical element to change so as to mitigate aberration. Each orientation of the optical elements can be adjusted along one or more degrees of freedom. For example, each optical element (e.g., a reflective optical element, a transmissive optical element, etc.) may have six (6) degrees of freedom with which their orientation can be adjusted. For example, in Cartesian coordinates, each optical element may be adjusted along the x, y, and/or z-axes (e.g., +/−Δx, Δy, Δz), rotated along the x, y, and/or z-axes, or both. Therefore, by adjusting the orientation along one or more degrees of freedom, the wavefront induced by the light output by the illumination source combined with the wavefront induced by the orientation of the optical elements, can minimize an amount of wavefront drift (e.g., a magnitude of a difference between the wavefront provided by the optical projection system and a target or ideal wavefront expected to be output by the optical projection system).

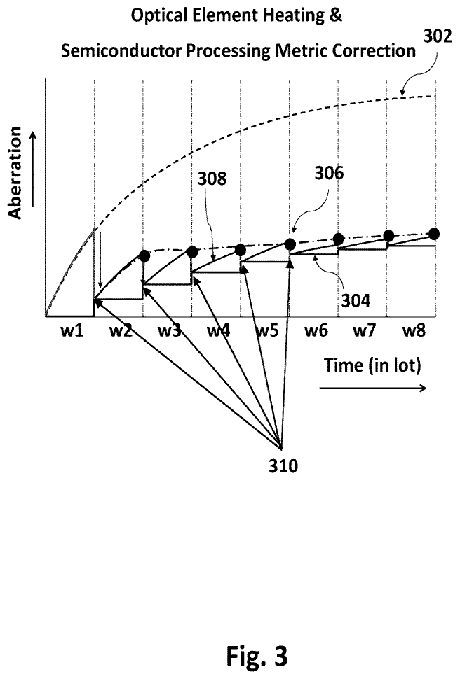

However, as mentioned above, as the power levels of the semiconductor processing apparatus increase, such as the light source in EUV scanners, the adjustments to the orientation of the optical elements is not enough to mitigate the heat induced by the light output by the illumination source. As the optical elements heat, the physical characteristics (e.g., shape, reflectivity, etc.) can change, resulting in wavefront drift and the patterning process creating products having defects. In particular, the defects can get worse as the number of wafers increases. For example, as seen with reference to FIG. 3, per-substrate (e.g., per wafer or per layer) dynamic aberration correction may be used to reduce defect count and size. Graph 300 of FIG. 3 uses mirror heating as an example. Graph 300 depicts changes in aberration (e.g., Zernikeᵢ) over time (in a given production lot) caused by mirror heating. Wafers 1-8 (e.g., w1, w2, . . . , w8) for a production lot are shown in graph 300. Furthermore, graph 300 plots a raw aberration drift 302 (e.g., change in Zernike over time caused by mirror heating) that would occur without correction. In contrast, FIG. 3 also shows, for each wafer, a mirror heating residual 308, a projection optics correction model residual 304, a last field 306 (which is equal to a worst mirror heating residual) for mirror heating residual 308, and a correction 310. The correction may be determined based on the projection optics correction model as described above. Due to the dynamic nature of the aberration impact model, corrections can be applied on a per-wafer basis, in contrast to prior art systems, which provided a static correction that can only be performed offline (e.g., not in a production manufacturing setting). At each wafer, the semiconductor processing metric (e.g., lithography metric) reduces the aberration impact a certain amount.

According to embodiments of the present disclosure, one or more thermal devices configured to apply thermal energy to one or more sections of one or more optical elements are controlled to mitigate the heating-induced imaging impact. For example, the thermal devices may be heaters configured to output irradiance directed at a particular section or sections of a given optical element. In some embodiments, the thermal devices may be used to adjust a contribution of a particular portion of an optical element to the overall heating state of the optical element so as to reduce wavefront drift (e.g., a difference between a wavefront provided by the optical projection system and a target wavefront). The amount of thermal energy to be output by the thermal device, and the location on the optical element with which the thermal energy is to be applied, may be adjusted according to imaging performance characteristics. For example, the adjustment is made so as to minimize the aforementioned EPE cost function or wavefront cost function. For example, with respect to Equation 2, the amount of thermal energy to be provided to a particular location of a particular optical element may be determined. The adjustment may be selected such that a wavefront generated by the wavefront model, which takes as input the heating state of the optical element induced by the thermal energy output by the thermal device and the heating state induced by the light output by the illumination source, combined with a wavefront generated based on the configuration of the optical element is as close to the target wavefront. For example, adjustments to the power level of the thermal device and adjustments to the configuration of the optical projection system can be made to minimize the following: WFM (HSᵢₗₗᵤₘᵢₙₐₜᵢₒₙ+HS_{SH})+WVF_{Dδ}−WVF_{Target}. Embodiments of the present disclosure are discussed in detail with reference to determining power or energy level of the thermal devices. However, it will be appreciated that this discussion is merely exemplary. Adjustments can be determined or made to one or more other different variables or parameter (e.g., current, voltage, location, orientation, etc.) associated with a thermal device without departing from the scope of the present disclosure, which may be dependent on the mechanical, electrical and logic configurations of the thermal device and the control or user interfaces.

As described above, a full simulation may include simulation of a source, a mask, a dose, a focus, and/or other aspects of a lithography process (e.g., see FIG. 2).

Advantageously, the aforementioned optimization process facilitates fast and dynamic scanner aberration (and wavefront) control that is imaging performance aware (e.g., such as for control of aberrations caused by mirror heating and/or other dynamic aspects of patterning equipment and/or a patterning process), effective for EUV scanners, DUV scanners, or scanners operating using other wavelengths of light, and incorporates the auxiliary thermal device contribution to the thermal state of the optical elements, where the power level can be high.

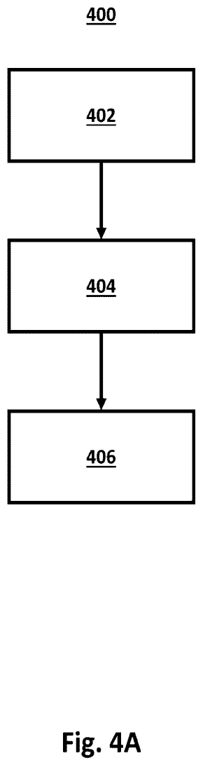

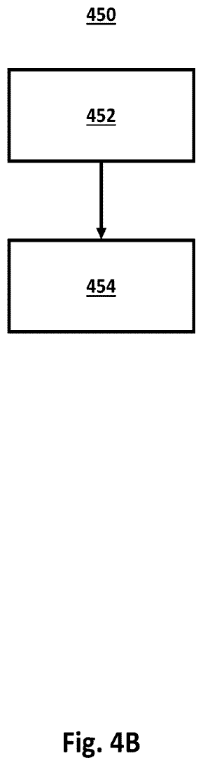

FIG. 4A illustrates an exemplary flowchart for determining process parameters associated with a thermal device, according to an embodiment. In some embodiments, method 400 includes an operation 402 including receiving wavefront data representing a wavefront provided by an optical projection system of a semiconductor processing apparatus. Method 400 further includes an operation 404 including determining wavefront drift based on a comparison of the wavefront data and target wavefront data. Method 400 still further includes an operation 406 including determining, based on the wavefront drift, one or more variables associated with the thermal device (e.g., process parameters of the thermal device).

In some embodiments, the variables that are determined can be used for dynamic in-situ aberration control of a patterning system (e.g., a semiconductor processing apparatus), and/or other operations. The operations of method 400 presented below are intended to be illustrative. In some embodiments, method 400 may be accomplished with one or more additional operations not described, and/or without one or more of the operations discussed. Additionally, the order in which the operations of method 400 are illustrated in FIG. 4A and described below is not intended to be limiting.

In operation 402, the wavefront data representing the wavefront data provided by the optical projection system may be received. The optical projection system may be part of a semiconductor processing apparatus (e.g., a lithography apparatus) used to generate a patterned device. In some embodiments, the wavefront data may be output by a wavefront sensor, which may be a physical sensor measuring wavefront at various locations along an optical path of the semiconductor processing apparatus. In some embodiments, the wavefront data is generated from a simulated sensor simulating a wavefront at one or more locations along the optical path of a modeled semiconductor processing apparatus, or both. In some embodiments, the wavefront may be generated based on a wavefront model. The wavefront model may take, as input, a heating state induced by light output from an illumination source of the semiconductor processing apparatus and a heating state induced by thermal energy output by a thermal device on an optical element of the optical projection system of the semiconductor processing apparatus. The output may be an induced wavefront from one or more thermal sources (e.g., where the illumination source and the thermal device both provide thermal energy to the optical element to heat the optical element). This induced wavefront may be computed with a wavefront induced by a configuration of the optical projection system. For example, the configuration of the optical projection system may include an orientation of one or more optical elements of the optical projection system. Different orientations of the optical elements may result in different wavefronts being induced.

In operation 404, wavefront drift may be determined based on a comparison of the wavefront data and the target wavefront data. The wavefront drift is a measure of a magnitude of a difference between a measured wavefront (e.g., a wavefront provided by the optical projection system) and a target wavefront represented by target wavefront data. The target wavefront depicts an ideal wavefront to be provided by the optical projection system if no aberration-related effects occurred. In some embodiments, the wavefront drift may be compensated so as to reduce a difference between the wavefront and the target wavefront. For example, the wavefront drift may be compensated by adjusting a configuration of the optical projection system, adjusting an amount of thermal energy provided to the optical projection system via a thermal device, adjusting a location along the optical projection system with which the thermal energy provided via the thermal device is applied, or via other techniques.

In operation 406, one or more process parameters may be determined based on the wavefront drift. The one or more process parameters may include parameters associated with a thermal device configured to provide thermal energy to the optical projection system. The thermal energy provided to the optical projection system may compensate for the impact from the wavefront drift, thereby reducing defect count and size. In some embodiments, the process parameters may be determined by minimizing a cost function, such as the cost function represented by Equation 2. For example, the cost function may be used to determined EPE costs or wavefront costs associated with different process parameters. Additionally, or alternatively, the determined EPE costs may be based on different configurations for the optical projection system.

FIG. 4B illustrates another exemplary flowchart for determining process parameters associated with a thermal device, according to an embodiment. In some embodiments, method 450 includes an operation 452 including obtaining a wavefront drift of a wavefront provided by an optical projection system of a semiconductor processing apparatus. The wavefront drift may be determined based on a comparison of wavefront data representing the wavefront and target wavefront data representing a target wavefront. Method 450 further includes an operation 454 including determining, based on the wavefront drift, one or more process parameters, where the process parameters include parameters associated with a thermal device configured to provide thermal energy to the optical projection system during operation.

In some embodiments, the one or more process parameters that are determined can be used for dynamic in-situ aberration control of a patterning system (e.g., a semiconductor processing apparatus), and/or other operations. The operations of method 450 presented below are intended to be illustrative. In some embodiments, method 450 may be accomplished with one or more additional operations not described, and/or without one or more of the operations discussed. Additionally, the order in which the operations of method 450 are illustrated in FIG. 4B and described below is not intended to be limiting.

In operation 452, the wavefront data drift may be obtained. In some embodiments, the wavefront drift may be computed by one or more components of the semiconductor processing apparatus (e.g., a wavefront sensor, control logic, a computer system coupled to the wavefront sensor, etc.). In some embodiments, the wavefront drift may be computed by a wavefront sensor communicatively coupled to a portion of the semiconductor processing apparatus. The wavefront drift is a measure of a magnitude of a difference between a measured wavefront (e.g., a wavefront provided by the optical projection system) and a target wavefront represented by target wavefront data. The target wavefront depicts an ideal wavefront to be provided by the optical projection system if no aberration-related effects occurred. In some embodiments, the wavefront drift may be compensated so as to reduce a difference between the wavefront and the target wavefront, or to optimize the imaging performance, e.g., by reducing the EPE cost or any other form of cost function that is known by those skilled in the art.

In some embodiments, the wavefront data may be detected by a wavefront sensor, which may be a physical sensor measuring wavefront at one or more locations along an optical path of the semiconductor processing apparatus. In some embodiments, a simulated sensor simulates a wavefront at one or more locations along the optical path of a modeled semiconductor processing apparatus. In some embodiments, the wavefront may be generated based on a wavefront model. In some embodiments, some or all of the steps associated with the wavefront simulation and/or wavefront detection may be performed offline, while other steps may be performed in-line during operation of the lithography apparatus. The wavefront model may take, as input, heating induced by light output from an illumination source of the semiconductor processing apparatus and heating induced by thermal energy output by a thermal device on an optical element of the optical projection system of the semiconductor processing apparatus. The output may be a predicted wavefront (e.g., where the illumination source and the thermal device both provide thermal energy to the optical element to heat the optical element). This wavefront may be computed with a wavefront induced by a configuration of the optical projection system. For example, the configuration of the optical projection system may include an orientation of one or more optical elements of the optical projection system. Different orientations of the optical elements may result in different wavefronts being induced.

In operation 454, one or more process parameters may be determined based on the wavefront drift. The one or more process parameters may include parameters associated with a thermal device configured to provide thermal energy to the optical projection system. The thermal energy provided to the optical projection system may compensate for the wavefront drift, thereby reducing defect count and size. In some embodiments, the process parameters may be determined by minimizing a cost function, such as the cost function represented by Equation 2. For example, the cost function may be used to determined EPE costs associated with different process parameters. Additionally, or alternatively, the determined EPE costs may be based on different configurations for the optical projection system.

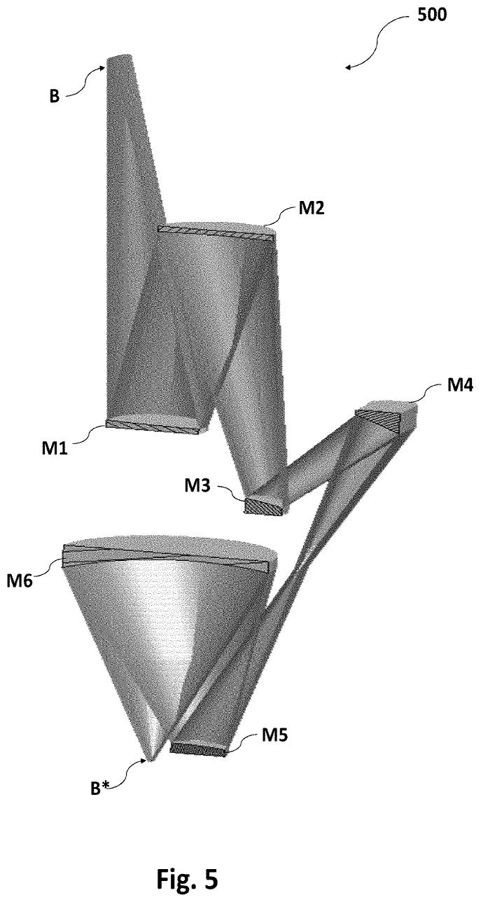

The optical projection system, as seen by FIG. 5, may include a set of optical elements. In the example of FIG. 5, optical projection system 500 may include six optical elements M1-M6. Beam B, which may be a patterned illumination beam resulting from light output from an illumination source being patterned using a patterning device, may incident optical elements M1-M6. Although the optical projection system 500 includes six optical elements, more or fewer optical elements may be used without deviating from the scope of the present application. Further still, while optical elements M1-M6 are depicted as being reflective optical elements (e.g., each optical element reflects incident light beam B instead of allowing the beam to pass through), one or more of optical elements M1-M6, or other optical elements of optical projection system 500, may be transmissive optical elements or partially reflective and partially transmissive.

Optical elements M1-M6 may condition beam B to form beam B*, which is configured to incident a mask to impart a pattern to a particular layer or wafer based on a configuration of the optical elements. For example, the configuration of the optical elements may indicate a shape of the optical elements, adjustments made to the optical elements along one or more degrees of freedom of the optical element (e.g., rotations, translational movements, along one or more axes), a material composition of the optical element, or other characteristics of the optical elements, or combinations thereof. The different configurations of the optical elements, alone or in combination with one another, can influence how subsequent aberrations will be induced to the resulting patterned devices (or layers of the patterned devices).

Light incident on an optical element can cause the optical element to change in temperature. The change in temperature caused by the incident light may vary across the optical element. For example, one section of the optical element may experience a change in temperature ΔT₁ while another section of the optical element may experience a different change in temperature ΔT₂. The difference changes in temperature can cause the optical element to deform by different amounts. For example, sections that experience a greater thermal change (e.g., sections that get “hotter”) may deform more than sections that experience a lesser thermal change. The deformations to the sections of the optical element can affect how the light provided by the optical element (e.g., the light transmitted through the optical element, the light reflecting off the optical element) is configured, which can impact accuracy of the patterning process. Thus, identifying which sections of the optical element (or elements) deform as a result of the thermal change caused by the incident light, and an extent of the deformations caused, can enable certain compensatory actions to be perform to the optical element.

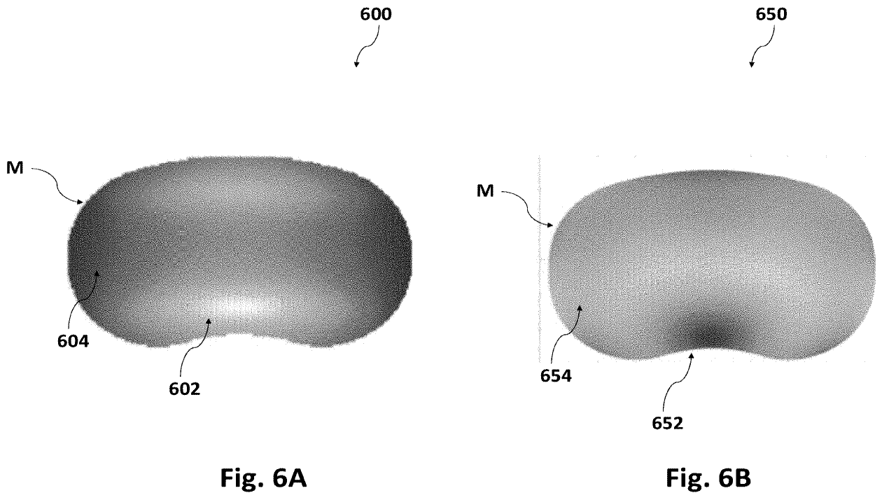

As an example, with reference to FIGS. 6A and 6B, optical element M may receive light output from an illumination source (e.g., an EUV source). The light may be incident on one or more other optical elements, patterned by a patterning device, or condition in other manners, before and/or after reflecting (or transmitting) from optical element M. For simplicity, the optical projection system is demonstrated to include a single optical element M. Thermal map 600 depicts a thermal response of optical element M as a result of incident light. In the example, the light may be continuous and optical element M may receive the continuous light for a predetermined amount of time to reach the particular thermal levels depicted by thermal map 600. Due to the configuration of optical element M, which may be caused naturally or may be specifically designed, the thermal levels across optical element M may vary. For example, region 602 may have a different thermal level than region 604 (e.g., region 602 may be “hotter” than region 604). The different thermal levels across optical element M can cause optical element M to deform. The extent of the deformation of a given region of optical element M may be related to the thermal level of that region. For example, as seen by deformation map 650 of FIG. 6B, region 652 may deform differently than region 654 of optical element M, where regions 652 and 654 of deformation map 650 corresponds respectively to regions 602 and 604 of thermal map 600. The greater the deformation to optical element M, the greater the aberration (e.g., defect count, defect size, etc.) may be to the resulting patterned devices.

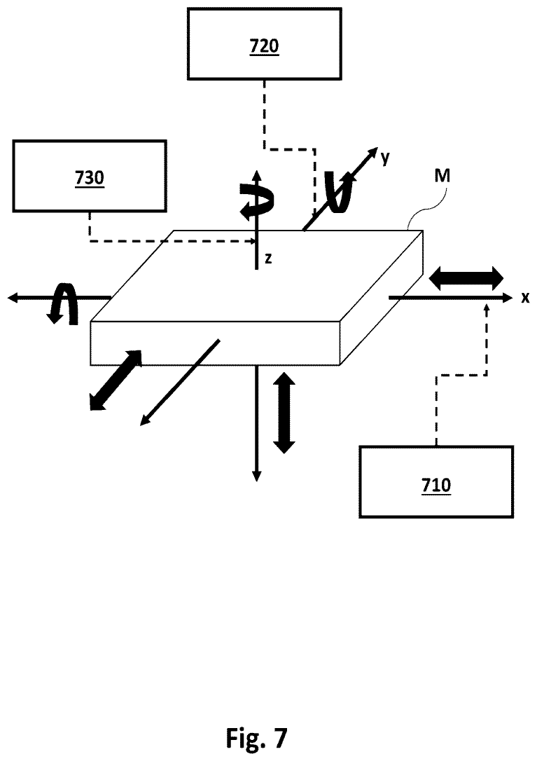

In some embodiments, adjusting an orientation of an optical element (e.g., an optical element included by an optical projection system of a semiconductor processing apparatus) can compensate for deformation to the optical element resulting from thermal changes. As an example, with reference to FIG. 7, an orientation of optical element M may be adjusted along one or more degrees of freedom of optical element M. As illustrated in FIG. 7, an orientation of optical element M may be adjusted along each of the x, y, or z-axes. The adjustments may be laterally (e.g., +Δx, +Δy, +Δz), rotationally (e.g., θₓ, θ_{y}, θ_{z}), or both laterally and rotationally. Furthermore, although optical element M is depicted as having its geometric center being centered at an origin of the coordinate system (e.g., Cartesian coordinate system), the alignment of optical element M with respect to the origin of the coordinate system may be shifted along one or more axes.

In some embodiments, one or more control devices may control adjustments made to an orientation of optical element M along one or more degrees of freedom. For example, control devices 710, 720, 730 may be configured to adjust the orientation of optical element M along the x, y, and z axes respectively. However, in some embodiments, additional control devices or fewer control devices may be included to control the movements of optical element M. Control devices 710, 720, 730 may include one or more actuators or other machines configured to control motion of optical element M. For example, control devices 710, 720, 730 may include one or more scanner control knobs. The amount with which optical element M is adjusted may be represented by δ (e.g., δ represents variable scanner control knob settings).

In some embodiments, the wavefront induced by the configuration of the optical projection system may be determined by using a dependency matrix D which correlates the scanner performance fingerprint with the scanner knob tunning. A scanner performance fingerprint, defined as WVF_{Dδ} in Equation 2, can be represented as D*δ, where δ represents variable scanner control knob settings. The scanner performance fingerprint may indicate a correction to be made to an orientation of an optical element. Determining the correction may include optimizing a cost function (e.g., achieving a minimum EPE or wavefront aberration cost). Embodiments of the present disclosure are discussed in detail with reference to EPE cost function. However, this discussion is merely exemplary. Any other form of cost function including any other suitable performance characteristics or metrics may be used without departing from the scope of the present disclosure. In some embodiments, the aberration impact may be modeled to determine optimized values for the terms of Equation 2. In some embodiments, the aberration impact model may be generated during an offline or research and development phase, and then used on a lithography apparatus during operation. The aberration impact model may be calibrated based on simulated patterning system aberration calibration data and/or corresponding patterning process impact calibration data. Simulations may be performed with a simulation engine based on different mask designs, pupil shapes, and/or other information. In some embodiments, the simulation may be performed on a full-chip layout and thereby the resulting cost function (e.g., Equation 2), dependency matrix (e.g., optical element orientation dependency matrix D), or Hessian matrix accounts for the full-chip layout. As described herein, a cost function from the aberration impact model is configured for use by a projection optics correction model (in combination with measured aberration data from a scanner (patterning system)) to determine a set of patterning process control metrics, and facilitate dynamic in-situ aberration control. The set of patterning process control metrics may include one or more process parameters, which may include parameters associated with a thermal device or devices configured to provided thermal energy to an optical projection system (e.g., optical elements of the optical projection system). The aberration impact model may take the form of an ADELasla file, for example, and/or any other scanner friendly light weight data format. In some embodiments, a single calibrated aberration impact model may be used by several different projection optics correction models (associated with several different scanners).

In some embodiments, dynamic in-situ aberration control may include adjusting, while in a manufacturing phase, one or more aspects of the semiconductor device manufacturing process. Adjustments may be made based on output from a projection optics correction model and/or other information. Manufacturing process parameter adjustments may be determined (e.g., an amount a given parameter should be changed), and the manufacturing process parameters may be adjusted from prior parameter set points to new parameter set points, for example. According to embodiments of the present disclosure, the adjustment can be made to a power level to be provided to a thermal device to cause thermal energy to be applied to an optical element, a location of where the thermal energy will be applied on the optical element, and/or other process parameters associated with the thermal devices. In addition, a pupil shape, a dose, a focus, a power setting, a material composition can also be adjusted as a result of the model.

Still further, the process parameters may be a configuration of the optical projection system, and a scanner may adjust the configuration of one or more aspects of the optical projection system. For example, the scanner may adjust an orientation of one or more optical elements along one or more degrees of freedom of the optical element. Adjustments to the orientation may be made to induce a wavefront that is used to minimize an EPE cost. In some embodiments, the adjustments can be made in-situ to dynamically control aberration impact.

The process parameters may be related to an amount of thermal energy to be provided to the optical projection system during operation (e.g., operation of the scanner) by a thermal device. In some embodiments, one or more of thermal devices may be used to provide thermal energy to the optical projection system to compensate for wavefront drift resulting from thermal heating of the optical projection system. The thermal energy provided by the thermal devices may reduce or redistribute the thermal energy about the optical projection system to achieve a more uniform and/or desired thermal distribution. For example, for EUV illumination sources, the additional energy of the EUV light may cause deformation to components of the optical projection system (e.g., optical elements, for example mirrors, included by the optical projection system may deform in shape due to heating resulting from the incident EUV light). The resulting deformation can cause the wavefront provided by the optical projection system to a target to shift relative to a target wavefront, which is referred to as wavefront drift. While adjusting the configuration of the optical projection system can help to reduce the wavefront drift, the limited adjustments available to the optical projection system may not compensate the wavefront drift enough to minimize defect count and size. For example, as mentioned above, while optical elements in the optical projection system may be adjusted along one or more degrees of freedom, the extent of those adjustments is limited by the size and shape of the optical elements and the other components of the semiconductor processing apparatus. The thermal devices may function as auxiliary thermal energy sources for inducing a particular wavefront, or contribution to a wavefront, to compensate for wavefront drift. For example, as seen by Equation 2, the wavefront generated by the wavefront model WFM may be based on two components: (1) a heating state HSᵢₗₗᵤₘᵢₙₐₜᵢₒₙ induced to the optical projection system by the light output from the illumination source, and (2) a heating state HS_{SH} induced by thermal devices providing thermal energy to specific sections of the optical projections (e.g., sections of an optical element). The net effect of the heating state from the thermal devices can be effective in reducing the wavefront drift in EUV applications such that the EPE cost function is minimized.

In some embodiments, the configuration of the optical projection system may include a material composition of some or all of the one or more optical elements of the optical projection system. For example, different material properties of the optical elements may result in more or fewer defects and/or reduced defect size. For example, different material compositions of the optical element may produce different performance based on the zero cross temperature (ZCT). For instance, as the ZCT increases, the defect counts and the maximum defect size may both decrease.

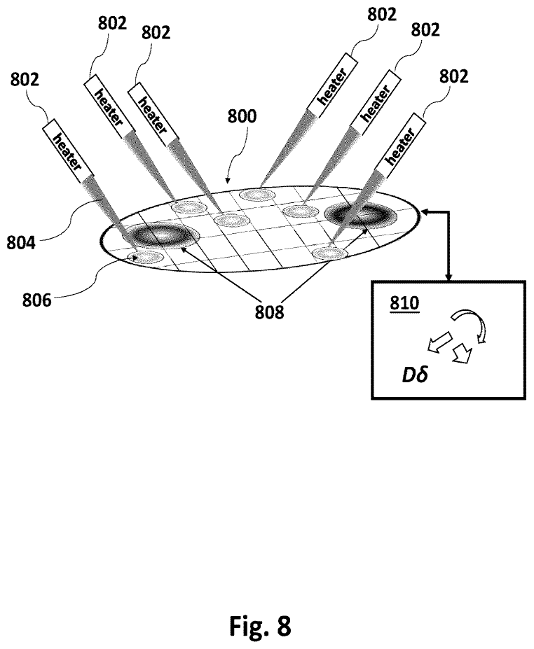

FIG. 8 illustrates an optical element 800 and a set of thermal devices 802 providing thermal energy 804 to optical element 800, according to an embodiment. As mentioned above, optical element 800 may be one of a set of optical elements included within an optical projection system of a semiconductor processing apparatus. For simplicity, a single optical element is depicted.

Light, such as EUV light, or other radiation, may incident one or more sections of optical element 800. The sections of optical element 800 where the light is applied may be predetermined based on a configuration of the optical projection system, the light, or other optical components. For example, based on a pupil, reticle, or other component of semiconductor processing apparatus, the EUV light may be applied to spots 808 located on a first surface of optical element 800. Alternatively or additionally, the EUV light may be applied to another surface of optical element. In some embodiments, a magnitude (e.g., an intensity) of the incident EUV light may vary depending on the particular processing design. The EUV light may increase (or decrease) a temperature of some or all of optical element 800. The temperature distribution across the optical element represents the “heating state” of the optical element. The heating state may be a “total” or “overall” heating state of the particular optical element or elements, and may have a contribution from the illumination source's output light and any additional thermal energy provided to the optical elements from thermal devices 802. As mentioned previously, thermal devices 802 may provide thermal energy directed at one or more sections of optical element 800 so as to modify the temperature distribution of optical element 800, thereby reducing a different between a transient wavefront detected by a wavefront sensor (e.g., representing the wavefront provided by the optical projection system) and a target wavefront. For example, by adding a particular amount of thermal energy to a particular location or locations of an optical element can reduce the wavefront drift by modifying a temperature distribution across the optical element so as to make the temperature distribution closer to a temperature distribution that would produce the target wavefront.

In some embodiments, optical element 800 may include one or more thermal devices 802. Thermal devices 802, which may also be referred to as “section heaters,” may be configured to output thermal energy 804 directed at a particular location or locations of optical element 800. In some embodiments, the output thermal energy may be in the form of irradiance. Thermal energy 804 may be applied to certain locations 806. Locations 806 may be determined based on calibration data. The calibration data may be generated by simulating wavefront created by heating states induced by various temperature distributions of the optical element. Adding specific amounts of thermal energy to specific locations on the optical element can cause the temperature distribution to modify in a particular manner. The thermal energy and locations with which irradiance output by thermal device 802 may then be determined so as to cause the temperature distribution of the optical element to be closer to that which induces the heating state producing the target wavefront. As a result, dynamic adjustments to the amount of thermal energy output by a given thermal device, and a location (e.g., a section) on the optical element where the thermal energy is to be applied, may be made to compensate for wavefront drift, thereby reducing a difference between the wavefront provided by the optical projection system and the target wavefront. Reducing the wavefront drift may be modeled by minimizing a cost function, such as the cost function of Equation 2, which computes the wavefront drift and weights the wavefront drift by one or more semiconductor processing metrics (e.g., lithography metrics). In another example, the cost function computes the cost of wavefront drift without computing the processing metrics.

Although multiple instances of thermal device 802 are illustrated in FIG. 8, each optical element of an optical projection system may include one or more instances of thermal device 802. Each thermal device 802 may be configured to output a same or different amount of thermal energy to one or more different sections of optical element. For example, a first section of optical element 800 may receive a first amount of thermal energy from an instance of thermal device 802, while a second section of optical element 800 may receive a second amount of thermal energy from another instance of thermal device 802. In some embodiments, a single thermal device may be used to apply thermal energy to one or more optical elements.

In addition to the thermal energy provided by the thermal devices (e.g., thermal devices 802), one or more control devices, such as control device 810, may be configured to adjust a configuration of the optical projection system. For example, control device 810 may adjust an orientation of optical element 800 along one or more degrees of freedom to cause a particular wavefront to be generated by the configuration of optical element 800.

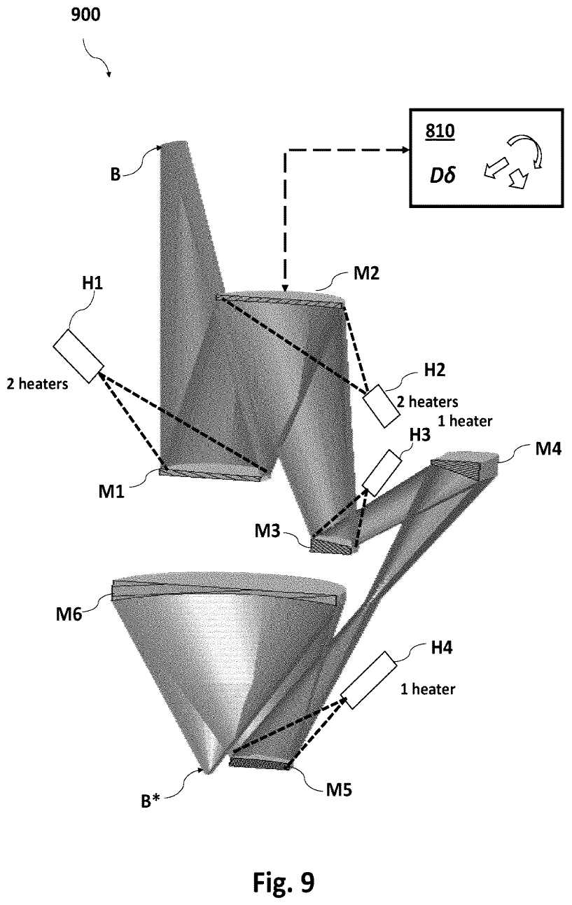

FIG. 9 illustrates an example optical projection system including optical elements, thermal devices used to provide thermal energy to some or all of the optical elements, and control devices for controlling an orientation of some or all of the optical elements, according to an embodiment. In some embodiments, optical projection system 900 may be similar to that of FIG. 5, with the addition of thermal devices for irradiating sections of various optical elements and control devices for adjusting an orientation of one or more of the optical elements. As an example, optical projection system 900 may include control device 810, which may include and/or be communicatively coupled to one or more actuators controlling an orientation of some or all of optical elements M1-M6. In some embodiments, optical projection system 900 may include multiple control devices 810 configured to control one or more of optical elements M1-M6.

Optical projection system 900 may also include thermal devices H1-H4. Thermal devices H1-H4 may be configured to output thermal energy (e.g., irradiate) one or more sections of one or more of optical elements M1-M6. In the example of FIG. 9, optical elements M1 and M4 may not receive thermal energy from thermal devices H1-H4, however optical projection system 900 may cause one or more additional thermal devices or one or more of thermal devices H1-H4 to dynamically adjust a directionality with which they output thermal energy so as to enable optical elements M1 and M4 to receive thermal energy. However, persons of ordinary skill in the art will recognize that additional or fewer thermal devices may be included.

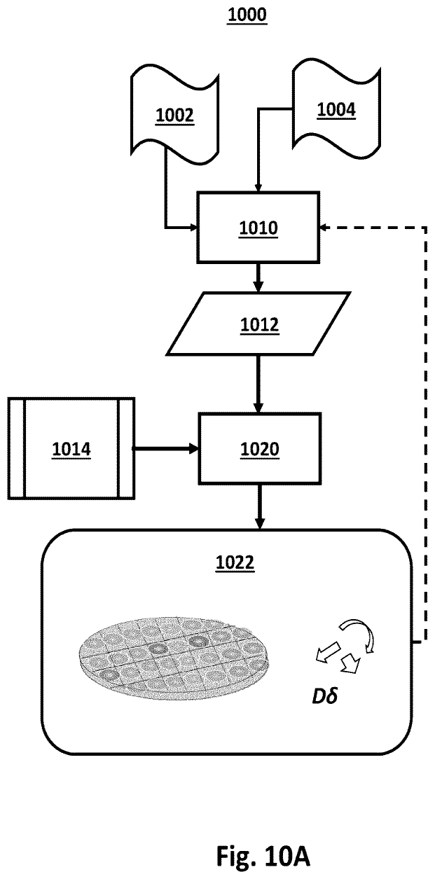

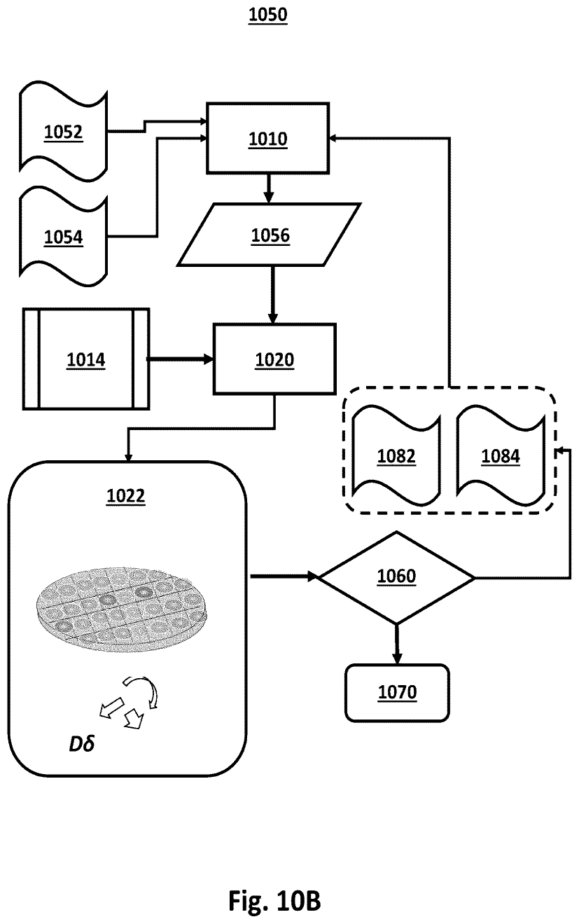

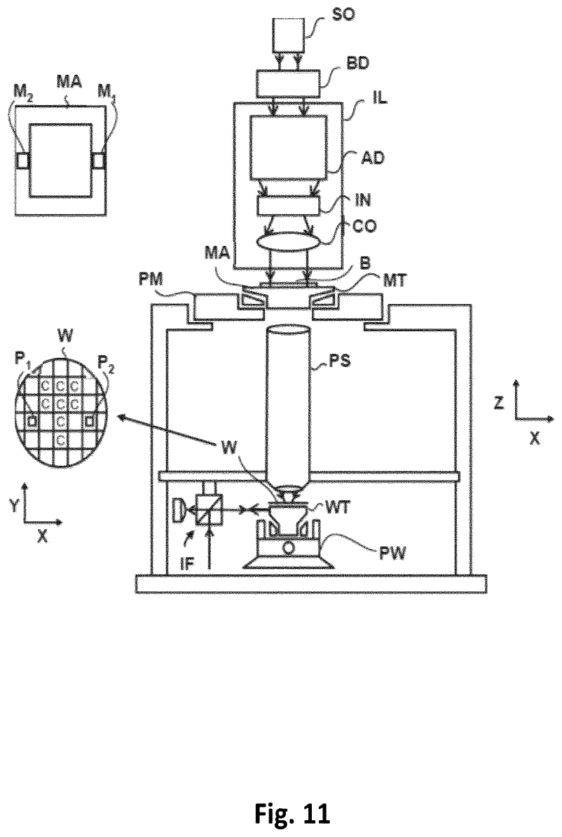

FIG. 10A illustrates an example method for performing aberration correction using an offline thermal device optimization process according to an embodiment. The offline modeling may be used to determine process parameters (e.g., operational settings) of a thermal device for a given exposure, or a sequence of exposures. In some embodiments, the offline modeling may use a steady state wavefront. In some embodiments, the modeling may use a current transient wavefront previously detected during an exposure operation. In some embodiments, the steady state wavefront may represent an expected wavefront derived or simulated from known exposure information. For example, the steady state wavefront may represent a wavefront predicted based on a particular output light, a reticle, or other features of the semiconductor processing apparatus. Additionally, the steady state wavefront is treated as not vary during a particular time period (e.g., during the processing of an individual wafer or set of wavers), and thus the resulting correction to the thermal devices and optical elements may remain the same. In some embodiments, method 1000 of FIG. 10A may include a simulation of an optical diffraction pattern. In some embodiments, method 1000 may include a simulation or empirically-determined event, which may be based on the generated optical diffraction pattern. The event may refer to events that occur during the semiconductor processing steps. For example, lithography exposure, delays and residuals during the patterning process may be a form of an event that can occur. In some embodiments, the steady stet wavefront may be empirical data (e.g., measured from previous processing on a sequence of wafers on the equipment). In some embodiments, method 1000 may include executing an offline thermal model. The offline thermal model may be combined with one or more lithography metrics to determine process parameters to be used to compensate for any wavefront drift. The model may generate a processing recipe or a sequence of recipes related to the thermal device. For example, the model may generate a sequence of values of a processing parameters of the thermal device that can be used during operation of the lithography process so as to control the aberration impact according to the given event of wafer processing, e.g., including a sequence of wafer loading, exposures, delays, pauses, in the temporal order, etc. In some embodiments, method 1000 may be used to compute the process parameters of the thermal devices and configurations of the optical projection system prior to a substrate being exposed to radiation.

Method 1000 may begin at operation 1010. In operation 1010, a wavefront may be generated using a wavefront generation model. The generated wavefront may be a simulated or measured result. In some embodiments, the wavefront generation model may take, as input, a heating state 1002 induced by a steady state wavefront provided by the optical projection system for a particular configuration. The heating state induced by the steady state wavefront may be represented by steady state wavefront data. In some embodiments, the wavefront generation model may additionally or alternatively take, as input, a heating state 1004 induced by one or more thermal devices outputting thermal energy to one or more sections of one or more optical elements of the optical projection system. The wavefront generation model may generate a simulated wavefront 1012 based on the heating state induced by the steady state wavefront and the heating state induced by the thermal energy output by the thermal devices to the optical elements.

In an operation 1020, an optimization process is performed to for use in dynamic in-situ aberration correction. The optimization process may receive simulated wavefront 1012, which may also be referred to as a “steady state” wavefront, and may also receive semiconductor processing metrics 1014. The optimization process of operation 1020 may be configured to determine aberration control data 1022, which may be used for performing dynamic in-situ aberration control of a semiconductor processing apparatus (e.g., a scanner and/or other patterning systems). In some embodiments, dynamic in-situ control of the scanner, or other components, includes generating a corrected scanner control parameter recipe for a given scanner aberration to optimize a set of lithography performance metrics. In some embodiments, aberration control data 1022 may be used to generate the scanner control parameter recipe. The scanner control parameter recipe, for example, may include determined process parameters associated with one or more thermal devices and/or determined configurations for the optical projection system. For example, the scanner control parameter recipe may include first instructions indicating an adjustment to process parameters associated with the thermal devices, and second instructions indicating an adjustment to a configuration of the optical projection system. The adjustment to the process parameters may include an adjustment to a power level of thermal energy output by the thermal device, an adjustment to a location where the thermal energy is to be applied to an optical element of the optical projection system, or other operational settings that may be adjusted, or combinations thereof. The adjustment to the configuration of the optical projection system may include an adjustment to an orientation (e.g., translational adjustment, rotational adjustment) of the optical element of the optical projection system.

In some embodiments, the optimization may be performed by minimizing a cost function (e.g., an EPE cost). For example, the cost function of Equation 2 may be minimized for certain process parameters and configurations. Aberration control data 1022 may indicate the process parameters and configurations that minimize the cost produced by the cost function.

In some embodiments, method 1000 may be repeated for each exposure. In some embodiments, for example, for a given exposure, heating state 1004 induced by the thermal energy provided to the optical element of the optical projection system by the thermal device may be updated. The updated version of heating state 1004 may be determined based on the adjustments to be made to the thermal energy provided by the thermal device (e.g., an amount and/or location) indicated by aberration control data 1022.

FIG. 10B illustrates an example method for performing aberration correction using in-line thermal device optimization process according to an embodiments of the present disclosure. The in-line modeling may be used to determine process parameters (e.g., operational settings) of a thermal device for a given exposure (e.g., wafer by wafer). The in-line modeling may use a current wavefront (which may be a transient or steady-state wavefront) detected after a given exposure or a wavefront derived therefrom. In some embodiments, method 1050 of FIG. 10B may include a simulation of an optical diffraction pattern. In some embodiments, method 1050 may include a simulation of an event, which may be based on the generated optical diffraction pattern. The event may refer to events that occur during the semiconductor processing steps. For example, delays and residuals during the patterning process may be a form of an event that can occur. In some embodiments, method 1050 may include executing an offline thermal model. The offline thermal model may be combined with one or more lithography metrics to determine process parameters to be used to compensate for any wavefront drift. In some embodiments, method 1050 may be used to compute the process parameters of the thermal devices and configurations of the optical projection system prior to a substrate being exposed to radiation.

Method 1050 may begin at operation 1010. Operation 1010 of method 1050 may be substantially similar to that of method 1000 with the exception that a heating state 1052 of a current wavefront and a heating state 1054 induced by current process parameters for a current exposure (e.g., wafer 1, wafer 2, . . . , wafer n) may be input to the wavefront generation model instead of a steady state wavefront's heating state. The wavefront generation model may be configured to generate simulated wavefront 1056 based on heating states 1052 and 1054.

In operation 1020, simulated wavefront 1056 and semiconductor processing metrics 1014 may be used to perform an optimization process for use in dynamic in-situ aberration correction. The optimization process may receive simulated wavefront 1056, which may also be referred to as a “transient” wavefront or “hot” wavefront, and may also receive semiconductor processing metrics 1014. The optimization process of operation 1020 may be configured to determine aberration control data 1022, which may be used for performing dynamic in-situ aberration control of a semiconductor processing apparatus (e.g., a scanner and/or other patterning systems). In some embodiments, dynamic in-situ control of the scanner, or other components, includes generating a corrected scanner control parameter recipe for a given scanner aberration to optimize a set of lithography performance metrics. In some embodiments, aberration control data 1022 may be used to generate the scanner control parameter recipe. The scanner control parameter recipe, for example, may include determined process parameters associated with one or more thermal devices and/or determined configurations for the optical projection system. For example, the scanner control parameter recipe may include first instructions indicating an adjustment to process parameters associated with the thermal devices, and second instructions indicating an adjustment to a configuration of the optical projection system. The adjustment to the process parameters may include an adjustment to a power level of thermal energy output by the thermal device, an adjustment to a location where the thermal energy is to be applied to an optical element of the optical projection system, or other operational settings that may be adjusted, or combinations thereof. The adjustment to the configuration of the optical projection system may include an adjustment to an orientation (e.g., translational adjustment, rotational adjustment) of the optical element of the optical projection system.

In some embodiments, the optimization may be performed by minimizing a cost function (e.g., an EPE cost). For example, the cost function of Equation 2 may be minimized for certain process parameters and configurations. Aberration control data 1022 may indicate the process parameters and configurations that minimize the cost produced by the cost function.

In some embodiments, method 1050 may be repeated for each exposure. For example, in operation 1060, a determination may be made as to whether a current batch has any more exposures. If not, then method 1050 may end at 1070. However, if additional exposures are to be performed (e.g., wafers 2, 3, etc.), then method 1050 may include generation of updated transient wavefront's heating state 1082 and updated process parameters' heating state 1084, which may be input to the wavefront generation model in operation 1010. The updated transient wavefront may represent a wavefront provided by the optical projection system after a given exposure ends, which includes information regarding an extent of the deformation to the optical elements of the optical projection system that occurred due to the incident light (e.g., EUV light) and incident irradiation from the thermal devices to perform in-situ aberration control for a prior exposure. Updated process parameters' heating state 1084 may represent a heating state to be induced to the optical elements by the thermal devices to compensate for the current wavefront drift.

In some embodiments, dynamic in-situ control includes control aberration during high volume manufacturing. For example, in some embodiments, method 1000 and/or method 1050 of FIG. 10B may be performed such that new patterning process impact data (e.g., the cost function output by the aberration impact model) is configured to facilitate enhanced compensation for, and/or control over, (e.g., EUV) heating of one or more mirrors, lenses, and/or other elements of the patterning system (e.g., to reduce and/or eliminate scanner aberrations) in real time or near real time during manufacturing. EUV mirror heating control is useful because a scanner typically needs to use a limited number of knobs to dynamically correct for an aberration induced by mirror heating. As another example, method 1000 and/or method 1050 of FIG. 10B may be performed such that the new patterning process impact data (e.g., the cost function output by the aberration impact model) is configured to facilitate enhanced control of a focus, a dose, and/or stage variation (MSD) associated with the patterning system (e.g., the scanner) in real time or near real time during manufacturing. Other examples are contemplated.

It should be noted that one aberration impact model can be provided to different projection optics boxes for control of CD, EPE, and/or other parameters. Because the aberration impact model may be configured such that the cost (merit) function is constructed from a simulation result, one can define (e.g., use for calibration) any desired metrics, such as CD, pattern placement error (PPE), EPE, CD asymmetry, best focus shift, defect count, etc. In this way, the present aberration-impact model may be configured to automatically reflect desired metrics.

In some embodiments, an aberration impact model may determine a cost function s (Z). The projection optics correction model defines a (scanner) lens (element—e.g., lens, mirror, etc.) dependence matrix D such that a scanner performance fingerprint=D*δ, where δ represents variable scanner control knob settings. In some embodiments, the cost function from the aberration impact model may be defined, via Equation 3, as:

$$s ( Z ( δ ) ) = s ( Δ Z + D δ ) , \qquad Equation 3$$

where ΔZ represents an aberration drift from the scanner, D is the dependency matrix, δ represents the variable scanner control knob settings, and Dδ represents the performance fingerprint (or in other words an indication of a needed correction). A non-linear optimizer may be used to minimize s(δ) such that δ*=argmin s(δ), where δ* represents a needed dynamic scanner knob correction. The cost function s(Z(δ)) is at its minimum, s=0. The projection optics correction model may adjust knobs (δ) in an effort to minimize the cost s(δ).

As described above, in some embodiments, new patterning process impact data (e.g., the cost function) from the aberration impact model may be configured to be used (e.g., by the projection optics correction model) to determine a set of patterning process control metrics. In some embodiments, the patterning process control metrics comprise lithography performance metrics (or “lithography metrics”), and/or other information. In some embodiments, the set of patterning process control metrics is configured to be determined by a linear solver and/or by other operations. In some embodiments, the cost function s may be represented as s=ΔZ^{T} HΔZ, where H is a cost function Hessian. For example, assume (for this example) the form of the aberration-impact model (and/or the cost function output by the aberration impact model) is a positive-definite quadratic such as:

$$s ( Z ) = - \frac{1}{2} {Z}^{T} HZ = \frac{1}{2} {\sum }_{ij} {h}_{ij} {Z}_{i} {Z}_{j} , \qquad Equation 4$$

where the total aberration Z=ΔZ+D δ, ΔZ is the aberration drift (e.g. aberration induced by mirror heating), and δ represents the scanner knobs and D δ represents the correction. Then, Equation 4 may be rewritten as Equation 5:

$$s ( δ ) = \frac{1}{2} {( Δ Z + D δ )}^{T} H ( Δ Z + D δ ) . \qquad Equation 5$$

The above cost function can be converted into a set of lithography metrics. In some embodiments, the new patterning process impact data from the model comprises a cost function Hessian (e.g., H in the equation(s) above). Determining the set of patterning process control metrics comprises performing a singular value decomposition (SVD) on the Hessian. The Hessian (H) is a positive-definite matrix. Performing SVD on the Hessian converts the cost function it into the format of a “lithometric”.

In some embodiments, a singular value decomposition (SVD) may be performed on the Hessian according to Equation 6:

$$\frac{1}{2} H {⟶}^{SV D} {L}^{T} L , \qquad Equation 6$$

(where the Eigenvalues are absorbed into the Eigenvectors) such that:

$$\frac{1}{2} {( Δ Z + D δ )}^{T} H ( Δ Z + D δ ) = {( Δ Z + D δ )}^{T} {L}^{T} L ( Δ Z + D δ ) = {\vert L ( Δ Z + D δ ) \vert}^{2} , \qquad Equation 7$$

where SVD essentially eliminates cross terms via a high-dimensional rotation.

In some embodiments, Equation 7 above can be modified based on the additional features described above with respect to the thermal energy output by the thermal devices, which may yield Equation 2. For example, the wavefront generation model may take, as input, a term related to a heating state induced by the thermal devices on the optical elements of the optical projection system.

In some embodiments, the aberration impact model may be a prediction model. Calibration may include model generation, training, tuning, and/or other operations. The model may be calibrated with patterning system aberration calibration data and corresponding patterning process impact calibration data. The patterning system may be and/or include a scanner (such as the lithographic projection apparatus shown in FIG. 1 and in later figures). In a scanner, an aberration may occur when the surface of an optical element (e.g., a lens, a mirror, and/or other elements) of an optical projection system of a semiconductor processing apparatus (e.g., a scanner) is not in an intended position. The surface of the lens element may not be in an intended position because of lens element heating, for example, but may have many different causes. Patterning system aberration data includes data that describes the characteristics of a particular aberration, causes of the aberration, and/or other data. Patterning system aberration data may include measured and/or simulated aberrations, system and/or process parameters associated with an aberration, and/or other wavefront information. A wavefront aberration (or “aberration” as used herein) may refer to a deviation (degree of disagreement) between an ideal wavefront and an actual wavefront. As described herein, wavefront aberration may referred to herein interchangeably as “wavefront drift.”

For example, when a lens element heats up, shape changes (which cause aberrations) may be caused by a laser power level, a pupil shape, a target design, an exposure dose, and/or other factors. Any and/or all of these and other factors may be included in a patterning system aberration data set. Patterning process impact data includes data that describes the effect an aberration has on a corresponding patterning process. For example, patterning process impact data may be indicative of an impact, by a corresponding patterning system aberration, on imaging performance on a substrate, for example a critical dimension, a pattern placement error, an edge placement error, critical dimension asymmetry, a best focus shift, a defect count associated with a patterning process, and/or other parameters. Patterning process impact data may include values for various parameters, cost and/or merit functions (e.g., as described below), and/or other information.

Patterning system aberration calibration data and corresponding patterning process impact calibration data comprise known and/or otherwise previously determined data. The patterning system aberration and/or process impact calibration data may be measured, simulated, and/or determined in other ways. In some embodiments, the calibration data is obtained by executing a full simulation model based on associated pupil shapes, patterning device designs, and various aberration inputs (e.g., where the full simulation model may include one or more of illumination model 31, projection optics model 32, design layout model 35, resist model 37, and/or other models).

In some embodiments, the aberration impact model is calibrated by providing the patterning system aberration calibration data to a base (prediction) model to obtain a prediction of the patterning process impact calibration data, and using the patterning process impact calibration data as feedback to update one or more configurations of the base model. For example, the one or more configurations of the aberration impact are updated based on a comparison between the patterning process impact calibration data and the prediction of the patterning process impact calibration data. The calibration data used for calibrating the aberration impact model may include pairs or sets of inputs (e.g., known patterning system aberration data) and corresponding known outputs (e.g., known patterning process impact calibration data). In some embodiments, the aberration impact model may self-learn using the provided pairs of training information. A calibrated aberration impact model can then be used to make predictions (e.g., on patterning process impact) based on various input information such as different patterning system aberration data as described above.

In some embodiments, the aberration impact model comprises a hyperdimensional function configured to correlate the received patterning system aberration data with patterning process impact data. In some embodiments, calibrating the model comprises updating one or more configurations of the base model by tuning and/or otherwise adjusting one or more parameters of the function. In some embodiments, tuning comprises adjusting one or more model parameters such that predicted patterning process impact data better matches, or better corresponds to, known patterning process impact calibration data. In some embodiments, tuning comprises training or re-training the model using additional calibration information comprising new and/or additional input/output calibration data pairs.

In some embodiments, the aberration impact model (e.g., the hyperdimensional function) comprises one or more of a non-linear algorithm, a linear algorithm, a quadratic algorithm, or a combination thereof but can and/or include any suitable arbitrary mathematical function. For example, the hyperdimensional function may have any arbitrary power polynomial form, a piece-wise polynomial form, exponential forms, Gaussian forms, sigmoid forms, decision-tree type of forms, convolutional neural network type of forms, etc. These algorithms may include any number of parameters, weights, and/or other features, in any combination such that the hyperdimensional function is configured to mathematically correlate patterning system aberrations with patterning process impact in a simplified form in lieu of a full simulation. Without limiting the scope of the present disclosure to the following examples, an example linear algorithm may include linear forms of Zernike terms, where the linear coefficients are computed via a linear regression of the dependency of CD, PPE, EPE, asymmetry, defects, and/or other parameters on individual Zernike terms. An example quadratic algorithm may include linear and quadratic forms of Zernike terms, where the linear and quadratic coefficients are computed via a non-linear regression of the dependency of CD, EPE, PPE, and/or other parameters on individual Zernike terms.

In some embodiments, the form of the function (e.g., non-linear, linear, quadratic, etc.), the parameters of the function, the weights in the algorithm, and/or other characteristics of the function may be determined automatically based on the calibration described above, based on accuracy and runtime performance specifications provided by a user, based on manual entry and/or selection of information by a user through a user interface included in the present system, and/or by other methods. In some embodiments, the form of the function (e.g., non-linear, linear, quadratic, etc.), the parameters of the function, and/or other characteristics of the function may change with individual layers of a substrate (e.g., as processing parameters and/or other conditions that might cause and/or affect aberrations change), and/or based on other information. For example, different models may be calibrated for different layers of a substrate produced during semiconductor device manufacturing pattering operations.

Dynamic in-situ aberration control comprises adjusting, while in a manufacturing phase, the semiconductor device manufacturing process. Adjustments may be made based on output from a projection optics correction model and/or other information. Manufacturing process parameter adjustments may be determined (e.g., an amount a given parameter should be changed), and the manufacturing process parameters may be adjusted from prior parameter set points to new parameter set points, for example. In some embodiments, the determined and/or adjusted semiconductor device manufacturing process parameters comprise one or more of a pupil shape, a dose, a focus, a power setting, and/or other semiconductor device manufacturing process parameters. As an example, if the process parameter were a (e.g., new) pupil shape, or a new dose, a scanner could be adjusted from an old or previous pupil shape, or dose, to the determined (e.g., new) pupil shape, or dose. Several other similar examples are contemplated.

As described above, the model(s) described herein may have a wide range of applications. Another example application (e.g., beyond the mirror-heating and other examples described above) is co-optimization of multiple patterning systems using aberration impact modeling. A patterning system may include a scanner and/or other patterning systems. For example, calibrated aberration impact models can be used for wavefront tuning (e.g., instead of the full imaging simulations in the prior art systems) to ensure the same design layout prints the same on different scanners or at different slit locations.

As a reminder, an aberration impact model as described herein comprises a relatively simple hyperdimensional function configured to correlate the received patterning system aberration data with the new patterning process impact data. The hyperdimensional function is configured to correlate the received patterning system aberration data with the new patterning process impact data in an approximation form in lieu of a full simulation (without calculation of an aerial image). Multiple models can be used to describe the imaging performance of multiple scanners.

The present (aberration impact) model(s) are compact models with a reduced scope and improved runtime performance relative to prior models. The present models lend themselves to the co-optimization application at least because predicted impact is based (only) on aberration data, and the predicted impact may be specifically applied to pre-selected metrics such as critical dimensions, defect counts, etc.), which makes the models accurate, fast, and/or have other advantageous features. The present models can be dedicated for use cases where tuning is based only on relevant aberration data. Co-optimization of multiple patterning systems is possible because of the light weight nature of the present models and/or their other advantageous features.

For example, in some embodiments, one or more processors (e.g., one or more computers) may execute one or more electronic models (e.g., aberration impact models) for determining patterning process impact data without calculation of a patterning process aerial image representation. The patterning process impact data may be configured to facilitate co-optimization of multiple patterning systems used in a patterning process. The new patterning process impact data output from the model may be configured to facilitate co-optimization of multiple scanners used in the patterning process. Co-optimization may comprise using lens actuators as variables, and a gradient based non-linear optimizer to co-determine actuator positions for multiple scanners. In some embodiments, the new patterning process impact data from the model is configured to be used to determine a set of patterning process control metrics, with the set of patterning process control metrics configured to be determined by a linear solver (e.g., as described below).

Patterning system aberration data may be provided to a model (or multiple models) so that the model(s) (e.g., hyperdimensional functions) correlate the received patterning system aberration data with patterning process impact data. Different (aberration impact) models may correspond to different patterning systems (scanners). New patterning process impact data may be determined for the received patterning system aberration data. By way of a non-limiting example, the received patterning system aberration data may comprise received wavefront data, and the new patterning process impact data may comprise one or more patterning process metrics. Wavefront data may comprise measured or simulated wavefront data in the form of a Zernike list or pixelated bitmap, for example, and/or other wavefront data. In this example, the one or more patterning process metrics may include a critical dimension, a pattern placement error, an edge placement error, critical dimension asymmetry, a best focus shift, a defect count associated with a patterning process, and/or other metrics. In some embodiments, the new patterning process impact data is indicative of an impact, by a corresponding patterning system aberration, on one or more of a critical dimension, a pattern placement error, an edge placement error, critical dimension asymmetry, a best focus shift, a defect count associated with a patterning process, and/or other metrics.

In some embodiments, a given model comprises one or more critical feature components (e.g., one or more dimensions of a hyperdimensional function) configured to model scanner to scanner variation for critical features of a patterning process; one or more regulation components (e.g., one or more other dimensions of the hyperdimensional function) configured to model generic performance across scanners for non-critical features of the patterning process, and/or other components. The critical feature components of a given model are defined for (all) of the patterning systems (e.g., scanners) in a group of patterning systems that are being co-optimized. The critical feature components are configured to represent patterning system (e.g., scanner) to patterning system variation for critical features (e.g., critical dimension as one example) in a pattern. The regulation components of a model may be configured to represent non-critical features of a pattern. The regulation components of a model may represent generic performance of a given scanner (or other patterning systems) with respect to non-critical features of a pattern. This separate critical feature component/regulation component arrangement may allow users to customize the critical feature components of a model based on patterning system performance at a given manufacturing location for example, or other unique factors that affect critical features of a patterning process, while keeping non-varying or non-critical factors the same (or similar). For example, a user may provide a specific CD sensitivity that can be represented by the one or more critical feature components of the model for critical features of a pattern, but then allow the regulation components of the model to generate output for non-critical features of a pattern, where it does not make sense to spend significant resources on modelling and/or optimization.

Put another way, critical features may be specified by the user according to any suitable criteria, e.g., may be features that the user specifically cares about and/or features that have one or more issues which need to be resolved. Other features may be deemed regulation features. The critical feature component(s) and the regulation component(s) of a given model may be two different functions associated with these different types of features. In some embodiments, a user can define regulation features/functions (e.g., in addition to and/or instead of critical feature components/functions), but if the user defines a regulation feature/function, the present system may be configured such that the user defined feature/function (by definition) becomes critical. Advantageously, any features/functions not specified by the user are handled by the model in a unified way known as the regulation features/functions.

In some embodiments, the new patterning process impact data from the model(s) is configured to be provided to a cost function to facilitate determination of costs associated with individual patterning process metrics and/or costs associated with individual patterning process variables. The costs associated with individual patterning process metrics and/or costs associated with individual patterning process variables are configured to be used to facilitate the co-optimization of the multiple scanners and/or for other purposes.

FIG. 11 is a schematic diagram of a lithographic projection apparatus, according to an embodiment. The lithographic projection apparatus can include an illumination system IL, a first object table MT, a second object table WT, and a projection system PS. Illumination system IL, can condition a beam B of radiation. In this example, the illumination system also comprises a radiation source SO. First object table (e.g., a patterning device table) MT can be provided with a patterning device holder to hold a patterning device MA (e.g., a reticle), and connected to a first positioner to accurately position the patterning device with respect to item PS. Second object table (e.g., a substrate table) WT can be provided with a substrate holder to hold a substrate W (e.g., a resist-coated silicon wafer), and connected to a second positioner to accurately position the substrate with respect to item PS. Projection system (e.g., which includes a lens) PS (e.g., a refractive, catoptric or catadioptric optical system) can image an irradiated portion of the patterning device MA onto a target portion C (e.g., comprising one or more dies) of the substrate W. Patterning device MA and substrate W may be aligned using patterning device alignment marks M1, M2 and substrate alignment marks P1, P2, for example.

As depicted, the apparatus can be of a transmissive type (i.e., has a transmissive patterning device). However, in general, it may also be of a reflective type, for example (with a reflective patterning device). The apparatus may employ a different kind of patterning device for a classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander, or beam delivery system BD (comprising directing mirrors, the beam expander, etc.). for example. The illuminator IL may comprise adjusting means AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus. The radiation beam that it produces may be led into the apparatus (e.g., with the aid of suitable directing mirrors), for example. This latter scenario can be the case when source SO is an excimer laser (e.g., based on KrF, ArF or F2 lasing), for example.

The beam B can subsequently intercept patterning device MA, which is held on a patterning device table MT. Having traversed patterning device MA, the beam B can pass through the lens PL, which focuses beam B onto target portion C of substrate W. With the aid of the second positioning means (and interferometric measuring means IF), the substrate table WT can be moved accurately, e.g. to position different target portions C in the path of beam B. Similarly, the first positioning means can be used to accurately position patterning device MA with respect to the path of beam B, e.g., after mechanical retrieval of the patterning device MA from a patterning device library, or during a scan. In general, movement of the object tables MT, WT can be realized with the aid of a long-stroke module (coarse positioning) and a short-stroke module (fine positioning). However, in the case of a stepper (as opposed to a step-and-scan tool), patterning device table MT may be connected to a short stroke actuator, or may be fixed.

The depicted tool can be used in two different modes, step mode and scan mode. In step mode, patterning device table MT is kept essentially stationary, and an entire patterning device image is projected in one operation (i.e., a single “flash”) onto a target portion C. Substrate table WT can be shifted in the x and/or y directions so that a different target portion C can be irradiated by beam B. In scan mode, essentially the same scenario applies, except that a given target portion C is not exposed in a single “flash.” Instead, patterning device table MT is movable in a given direction (e.g., the “scan direction”, or the “y” direction) with a speed v, so that projection beam B is caused to scan over a patterning device image. Concurrently, substrate table WT is simultaneously moved in the same or opposite direction at a speed V=Mv, in which M is the magnification of the lens (typically, M=¼ or ⅕). In this manner, a relatively large target portion C can be exposed, without having to compromise on resolution.

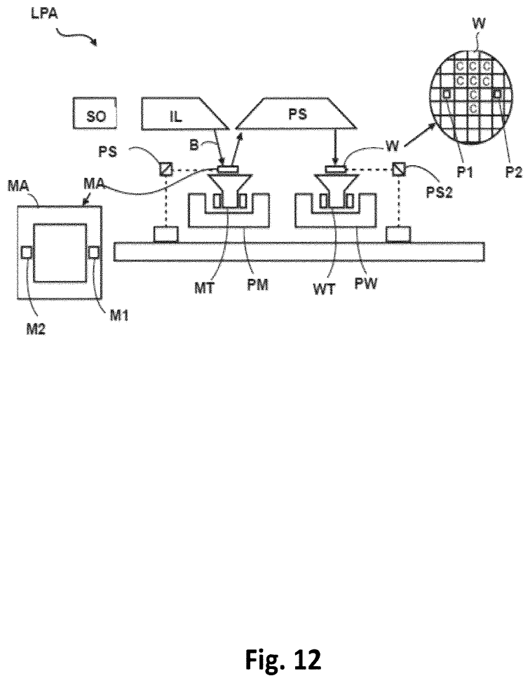

FIG. 12 is a schematic diagram of another lithographic projection apparatus (LPA) that may be used for, and/or facilitating one or more of the operations described herein. LPA can include source collector module SO, illumination system (illuminator) IL configured to condition a radiation beam B (e.g. EUV radiation), support structure MT, substrate table WT, and projection system PS. Support structure (e.g. a patterning device table) MT can be constructed to support a patterning device (e.g. a mask or a reticle) MA and connected to a first positioner PM configured to accurately position the patterning device. Substrate table (e.g. a wafer table) WT can be constructed to hold a substrate (e.g. a resist coated wafer) W and connected to a second positioner PW configured to accurately position the substrate. Projection system (e.g. a reflective projection system) PS can be configured to project a pattern imparted to the radiation beam B by patterning device MA onto a target portion C (e.g. comprising one or more dies) of the substrate W.

As shown in this example, LPA can be of a reflective type (e.g. employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has a 40 layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultra violet radiation beam from source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”), the plasma can be produced by irradiating a fuel, such as a droplet, stream or cluster of material having the line-emitting element, with a laser beam. Source collector module SO may be part of an EUV radiation system including a laser (not shown in FIG. 12), for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation. In this example, the laser may not be considered to form part of the lithographic apparatus and the radiation beam can be passed from the laser to the source collector module with the aid of a beam delivery system comprising, for example, suitable directing mirrors and/or a beam expander. In other examples, the source may be an integral part of the source collector module, for example when the source is a discharge produced plasma EUV generator, often termed a DPP source.

Illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held on the support structure (e.g., patterning device table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder, or capacitive sensor), the substrate table WT can be moved accurately (e.g. to position different target portions C in the path of radiation beam B). Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus LPA could be used in at least one of the following modes, step mode, scan mode, and stationary mode. In step mode, the support structure (e.g. patterning device table) MT and the substrate table WT are kept essentially stationary, while an entire pattern imparted to the radiation beam is projected onto a target portion C at one time (e.g., a single static exposure). The substrate table WT is then shifted in the X and/or Y direction so that a different target portion C can be exposed. In scan mode, the support structure (e.g. patterning device table) MT and the substrate table WT are scanned synchronously while a pattern imparted to the radiation beam is projected onto target portion C (i.e. a single dynamic exposure). The velocity and direction of substrate table WT relative to the support structure (e.g. patterning device table) MT may be determined by the (de) magnification and image reversal characteristics of the projection system PS. In stationary mode, the support structure (e.g. patterning device table) MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

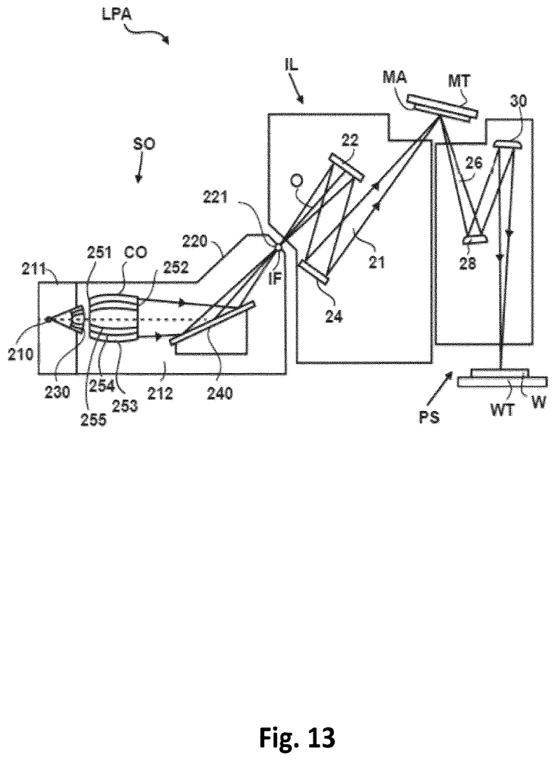

FIG. 13 is a detailed view of the lithographic projection apparatus shown in FIG. 12. As shown in FIG. 13, the LPA can include the source collector module SO, the illumination system IL, and the projection system PS. The source collector module SO is configured such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the hot plasma 210 is created to emit radiation in the EUV range of the electromagnetic spectrum. The hot plasma 210 is created by, for example, an electrical discharge causing at least partially ionized plasma. Partial pressures of, for example, 10 Pa of Xe, Li, Sn vapor or any other suitable gas or vapor may be required for efficient generation of the radiation. In some embodiments, a plasma of excited tin (Sn) is provided to produce EUV radiation.

The radiation emitted by the hot plasma 210 is passed from a source chamber 211 into a collector chamber 212 via an optional gas barrier or contaminant trap 230. In some embodiments also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier trap 230 (described below) also includes a channel structure. The collector chamber 211 may include a radiation collector CO which may be a grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the line “O”. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

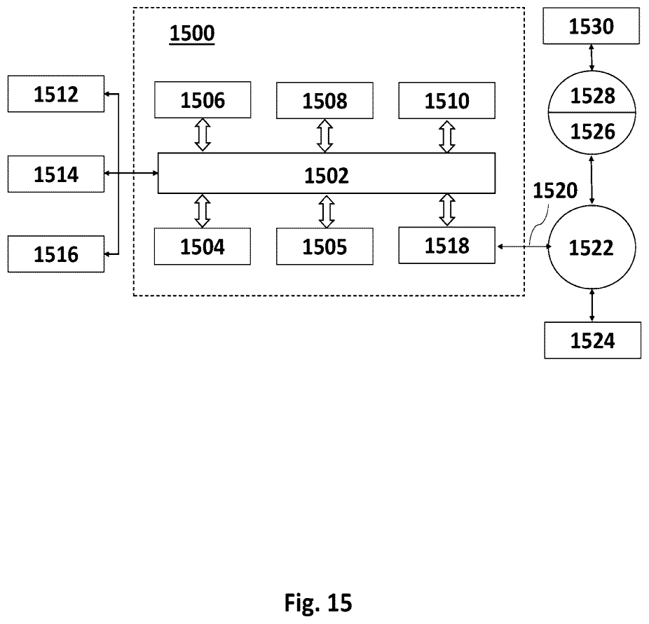

Subsequently, the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the substrate table WT. More elements than shown may generally be present in illumination optics unit IL and projection system PS. The grating spectral filter 240 may optionally be present, depending upon the type of lithographic apparatus, for example. Further, there may be more mirrors present than those shown in the figures, for example there may be 1-6 additional reflective elements present in the projection system PS than shown in FIG. 15.

Collector optic CO, as illustrated in FIG. 13, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type may be used in combination with a discharge produced plasma source, often called a DPP source.

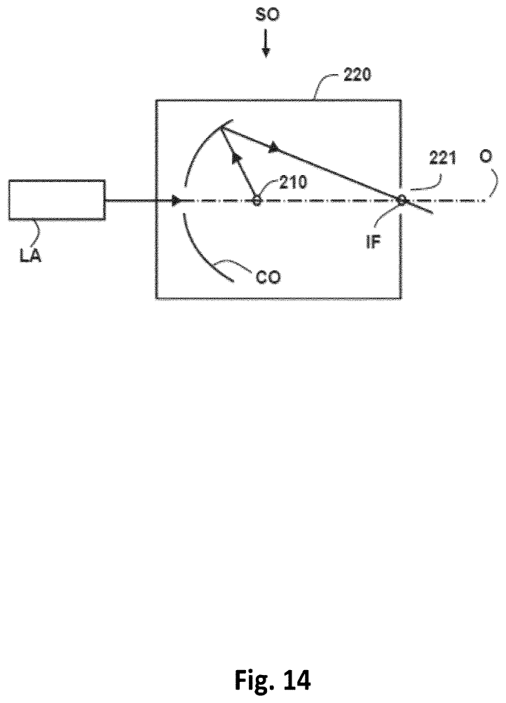

FIG. 14 is a detailed view of source collector module SO of the lithographic projection apparatus LPA (shown in previous figures). Source collector module SO may be part of an LPA radiation system. A laser LA can be arranged to deposit laser energy into a fuel, such as xenon (Xe), tin (Sn) or lithium (Li), creating the highly ionized plasma 210 with electron temperatures of several 10″'s of eV. The energetic radiation generated during de-excitation and recombination of these ions is emitted from the plasma, collected by a near normal incidence collector optic CO and focused onto the opening 221 in the enclosing structure 220.

Referring to FIG. 15, a computer system 1500 is shown. The computer system 1500 includes a bus 1502 or other communication mechanism for communicating information, and a processor 1504 (or multiple processors, such as processor 1504 and another processor 1505) coupled with bus 1502 for processing information. Computer system 1500 also includes a main memory 1506, such as a random access memory (RAM) or other dynamic storage device, coupled to bus 1502 for storing information and instructions to be executed by processor 1504. Main memory 1506 also may be used for storing temporary variables or other intermediate information during execution of instructions to be executed by processor 1504. Computer system 1500 further includes a read only memory (ROM) 1508 or other static storage device coupled to bus 1502 for storing static information and instructions for processor 1504. A storage device 1510, such as a magnetic disk or optical disk, is provided and coupled to bus 1502 for storing information and instructions.

Computer system 1500 may be coupled via bus 1502 to a display 1512, such as a cathode ray tube (CRT) or flat panel or touch panel display for displaying information to a computer user. An input device 1514, including alphanumeric and other keys, is coupled to bus 1502 for communicating information and command selections to processor 1504. Another type of user input device is cursor control 1516, such as a mouse, a trackball, or cursor direction keys for communicating direction information and command selections to processor 1504 and for controlling cursor movement on display 1512. This input device typically has two degrees of freedom in two axes, a first axis (e.g., x) and a second axis (e.g., y), that allows the device to specify positions in a plane. A touch panel (screen) display may also be used as an input device.

The computer system 1500 may be suitable to function as a processing unit herein in response to processor 1504 executing one or more sequences of one or more instructions contained in main memory 1506. Such instructions may be read into main memory 1506 from another computer-readable medium, such as storage device 1510. Execution of the sequences of instructions contained in main memory 1506 causes processor 1504 to perform a process described herein. One or more processors in a multi-processing arrangement may also be employed to execute the sequences of instructions contained in main memory 1506. In alternative embodiments, hard-wired circuitry may be used in place of or in combination with software instructions. Thus, embodiments are not limited to any specific combination of hardware circuitry and software.

The term “computer-readable medium” as used herein refers to any medium that participates in providing instructions to processor 1504 for execution. Such a medium may take many forms, including but not limited to, non-volatile media, volatile media, and transmission media. Non-volatile media include, for example, optical or magnetic disks, such as storage device 1510. Volatile media include dynamic memory, such as main memory 1506. Transmission media include coaxial cables, copper wire and fiber optics, including the wires that comprise bus 1502. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 1504 for execution. For example, the instructions may initially be borne on a magnetic disk of a remote computer. The remote computer can load the instructions into its dynamic memory and send the instructions over a telephone line using a modem. A modem local to computer system 1500 can receive the data on the telephone line and use an infrared transmitter to convert the data to an infrared signal. An infrared detector coupled to bus 1502 can receive the data carried in the infrared signal and place the data on bus 1502. Bus 1502 carries the data to main memory 1506, from which processor 1504 retrieves and executes the instructions. The instructions received by main memory 1506 may optionally be stored on storage device 1510 either before or after execution by processor 1504.

Computer system 1500 may also include a communication interface 1518 coupled to bus 1502. Communication interface 1518 provides a two-way data communication coupling to a network link 1520 that is connected to a local network 1522. For example, communication interface 1518 may be an integrated services digital network (ISDN) card or a modem to provide a data communication connection to a corresponding type of telephone line. As another example, communication interface 1518 may be a local area network (LAN) card to provide a data communication connection to a compatible LAN. Wireless links may also be implemented. In any such implementation, communication interface 1518 sends and receives electrical, electromagnetic or optical signals that carry digital data streams representing various types of information.

Network link 1520 typically provides data communication through one or more networks to other data devices. For example, network link 1520 may provide a connection through local network 1522 to a host computer 1524 or to data equipment operated by an Internet Service Provider (ISP) 1526. ISP 1526 in turn provides data communication services through the worldwide packet data communication network, now commonly referred to as the “Internet” 1528. Local network 1522 and Internet 1528 both use electrical, electromagnetic or optical signals that carry digital data streams. The signals through the various networks and the signals on network link 1520 and through communication interface 1518, which carry the digital data to and from computer system 1500, are exemplary forms of carrier waves transporting the information.

Computer system 1500 can send messages and receive data, including program code, through the network(s), network link 1520, and communication interface 1518. In the Internet example, a server 1530 might transmit a requested code for an application program through Internet 1528, ISP 1526, local network 1522 and communication interface 1518. In accordance with one or more embodiments, one such downloaded application provides for a method as disclosed herein, for example. The received code may be executed by processor 1504 as it is received, and/or stored in storage device 1510, or other non-volatile storage for later execution. In this manner, computer system 1500 may obtain application code in the form of a carrier wave.

An embodiment of the disclosure may take the form of a computer program containing one or more sequences of machine-readable instructions describing a method as disclosed herein, or a data storage medium (e.g. semiconductor memory, magnetic or optical disk) having such a computer program stored therein. Further, the machine readable instruction may be embodied in two or more computer programs. The two or more computer programs may be stored on one or more different memories and/or data storage media.

Any controllers described herein may each or in combination be operable when the one or more computer programs are read by one or more computer processors located within at least one component of the lithographic apparatus. The controllers may each or in combination have any suitable configuration for receiving, processing, and sending signals. One or more processors are configured to communicate with the at least one of the controllers. For example, each controller may include one or more processors for executing the computer programs that include machine-readable instructions for the methods described above. The controllers may include data storage medium for storing such computer programs, and/or hardware to receive such medium. So the controller(s) may operate according to the machine readable instructions of one or more computer programs.

Although specific reference may be made in this text to the use of a metrology apparatus in the manufacture of ICs, it should be understood that the metrology apparatus and processes described herein may have other applications, such as the manufacture of integrated optical systems, guidance and detection patterns for magnetic domain memories, flat-panel displays, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or one or more various other tools. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the disclosure in the context of optical lithography, it will be appreciated that the disclosure may be used in other applications, for example nanoimprint lithography, and where the context allows, is not limited to optical lithography. In the case of nanoimprint lithography, the patterning device is an imprint template or mold.

The concepts disclosed herein may simulate or mathematically model any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers. In addition, the combination and sub-combinations of disclosed elements may comprise separate embodiments. For example, determining enhanced MRC criteria may comprise its own separate embodiment, or it may be included with one or more other embodiments that also include performing the actual check, as described herein.

The concepts disclosed herein may simulate or mathematically model any generic imaging system for imaging sub wavelength features, and may be useful with emerging imaging technologies capable of producing increasingly shorter wavelengths. Emerging technologies include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

In addition, the combination and sub-combinations of disclosed elements may comprise separate embodiments. For example, the aberration impact model and the projection optics model may be included in separate embodiments, or they may be included together in the same embodiment.

The descriptions above are intended to be illustrative, not limiting. Thus, it will be apparent to one skilled in the art that modifications may be made as described without departing from the scope of the claims set out below.

Further embodiments according to the present application are described in the below enumerated clauses:

1. A method, comprising: receiving wavefront data representing a wavefront provided by an optical projection system of a semiconductor processing apparatus; determining wavefront drift based on a comparison of the wavefront data and target wavefront data; and determining, based on the wavefront drift, one or more process parameters, wherein the one or more process parameters comprises parameters associated with a thermal device, wherein the thermal device is configured to provide thermal energy to the optical projection system during operation.
2. The method of clause 1, wherein the wavefront data is determined based on (i) radiation, output by an illumination source, incident on an optical element of the optical projection system, and (ii) a configuration of the optical projection system.
3. The method of clause 2, wherein the optical projection system comprises one or more optical elements including the optical element, and the configuration of the optical projection system comprises an orientation of the one or more optical elements.
4. The method of clause 3, wherein each of the one or more optical elements has one or more degrees of freedom, and one or more control devices are configured to adjust the orientation of the one or more optical elements along at least one of the one or more degrees of freedom of at least one of the one or more optical elements.
5. The method of clause 4, wherein the one or more degrees of freedom comprises six degrees of freedom.
6. The method of any one of clauses 3-5, wherein the one or more optical elements comprise six optical elements.
7. The method of clause 6, wherein each of the six optical elements is a reflective optical element.
8. The method of any one of clauses 3-7, wherein each of the one or more optical elements is a transmissive optical element.
9. The method of any one of clauses 3-8, wherein the configuration of the optical projection system comprises a material composition of each of the one or more optical elements.
10. The method of any one of clauses 1-9, wherein the one or more process parameters comprises a set of operational settings of the thermal device.
11. The method of clause 10, wherein the set of operational settings of the thermal device comprises an amount of irradiance output from the thermal device.
12. The method of any one of clauses 10-11, wherein the set of operational settings of the thermal device comprises one or more sections of the optical projection system with which irradiance output by the thermal device is to be applied.
13. The method of clause 12, wherein the optical projection system comprises an optical element, the one or more process parameters comprise a location on the optical element where the irradiance output from the thermal device is to be applied.
14. The method of any one of clauses 10-13, wherein determining the one or more process parameters comprises: determining an adjustment to one or more operational settings of the set of operational settings of the thermal device based on the wavefront data, the target wavefront data, and one or more semiconductor processing metrics.
15. The method of clause 14, wherein the operations further comprise: determining, based on the wavefront drift, an adjustment to a configuration of the optical projection system.
16. The method of clause 15, wherein the one or more semiconductor processing metrics are computed based on radiation output from an illumination source and the configuration of the optical projection system.
17. The method of any one of clauses 15-16, wherein the operations further comprise: obtaining first instructions indicating the adjustment to be made to the one or more operational settings of the thermal device and second instructions indicating the adjustment to be made to the configuration of the optical projection system.
18. The method of clause 17, wherein the operations further comprise: providing the first instructions to the thermal device; and providing the second instructions to one or more control devices, the one or more control devices being configured to adjust the configuration of the optical projection system.
19. The method of clause 18, wherein the first instructions and the second instructions are provided simultaneously.
20. The method of any one of clauses 1-19, wherein the one or more process parameters are determined to compensate impact of the wavefront drift.
21. The method of clause 20, wherein compensating for impact of the wavefront drift comprises: determining an adjustment to the one or more process parameters associated with the thermal device; and determining an adjustment to a configuration of the optical projection system, wherein: the adjustment to the one or more process parameters associated with the thermal device and the adjustment to the configuration of the optical projection system are determined by minimizing a magnitude of the wavefront drift.
22. The method of clause 21, wherein minimizing the magnitude of the wavefront drift comprises: modifying the adjustment to the one or more process parameters associated with the thermal device and the adjustment to the configuration of the optical projection system until the wavefront drift satisfies a condition.
23. The method of clause 22, wherein the condition is satisfied responsive to determining, based on the wavefront data and the target wavefront data, that a difference between the wavefront and a target wavefront is less than a threshold wavefront drift value, wherein the target wavefront data comprises the target wavefront.
24. The method of any one of clauses 20-23, wherein compensating for impact of the wavefront drift comprises minimizing an edge placement error (EPE) cost or optimizing wavefront RMS.
25. The method of clause 24, wherein minimizing the EPE cost comprises: determining an adjustment to the one or more process parameters associated with the thermal device and an adjustment to a configuration of the optical projection system that yields a minimum EPE cost.
26. The method of clause 25, wherein the operations further comprise: determining the minimum EPE cost, wherein determining the minimum EPE cost comprises modifying the adjustment to the one or more process parameters associated with the thermal device and the adjustment to the configuration of the optical projection system until the EPE cost satisfies a condition.
27. The method of clause 26, wherein the condition is satisfied responsive to determining that the EPE cost is less than a threshold EPE cost.
28. The method of any one of clauses 24-27, wherein minimizing the EPE cost comprises: determining EPE costs of a cost function for a set of variables, wherein the set of variables comprises a plurality of process parameters associated with the thermal device and a plurality of configurations of the optical projection system; selecting, from the EPE costs, a minimum EPE cost; and extracting, based on the minimum EPE cost, one or more process parameters from the plurality of process parameters associated with the thermal device and one or more configurations of the optical projection system that produce the minimum EPE cost.
29. The method of clause 28, wherein the cost function computes an edge placement error (EPE) cost.
30. The method of any one of clauses 1-29, wherein the wavefront data is determined based on a heating state induced to one or more optical elements of the optical projection system by light output by an illumination source of the semiconductor processing apparatus and a heating state induced by the thermal device.
31. The method of clause 30, wherein the heating state induced by the thermal device is determined based on the one or more process parameters associated with the thermal device, the one or more process parameters comprising operational settings of the thermal device.
32. The method of clause 31, wherein the operational settings of the thermal device comprise a power level provided to the thermal device to cause the thermal device to output a prescribed amount of irradiance provided by the thermal device to the one or more optical elements of the optical projection system and one or more sections of at least one of the one or more optical elements with which the irradiance is to be applied.
33. The method of clause 32, wherein the heating state induced to the one or more optical elements by the light output by the illumination source of the semiconductor processing apparatus is determined based on a wavefront, detected via a wavefront sensor, after a portion of a semiconductor fabrication process executed by the semiconductor processing apparatus has been performed.
34. The method of any one of clauses 1-33, wherein the optical projection system comprises one or more optical elements, the thermal device is configured to output irradiance based on the one or more process parameters that are determined, and the irradiance output by the thermal device is applied to at least one of the one or more optical elements.
35. The method of clause 34, wherein the operations further comprise: determining one or more additional process parameters associated with an additional thermal device, wherein the additional thermal device is configured to output irradiance based on the one or more additional process parameters that are determined, the irradiance output by the additional thermal device being applied to at least one of: the at least one of the one or more optical elements, or at least another of the one or more optical elements.
36. The method of any one of clauses 1-35, wherein the thermal device is configured to improve correction capability of the semiconductor processing apparatus or the optical projection system.
37. The method of any one of clauses 1-36, wherein the one or more process parameters are application layer specific.
38. The method of any one of clauses 1-37, wherein the thermal device providing the thermal energy comprises the thermal device providing heating or cooling to the optical projection system.
39. The method of any one of clauses 1-38, wherein the thermal device is a heating device or a cooling device.
40. The method of any one of clauses 1-39, wherein the thermal energy comprises irradiance.
41. A method, comprising: obtaining a wavefront drift of a wavefront provided by an optical projection system of a semiconductor processing apparatus, wherein the wavefront drift is determined based on a comparison of wavefront data representing the wavefront and target wavefront data; and determining, based on the wavefront drift, one or more process parameters, wherein the one or more process parameters comprises parameters associated with a thermal device, wherein the thermal device is configured to provide thermal energy to the optical projection system during operation.
41. The method of clause 40, wherein the thermal energy comprises irradiance.
42. The method of clause 40, wherein the wavefront is comprises a steady state wavefront.
43. The method of clause 42, wherein the steady state wavefront is determined based on (i) a heating state induced to one or more optical elements of the optical projection system by light output by an illumination source of the semiconductor processing apparatus and (ii) one or more operational settings for causing the thermal device to provide the thermal energy to the one or more optical elements of the optical projection system.
44. The method of clause 43, wherein the one or more operational settings comprise: a power setting for the thermal device indicating an amount of irradiance to provide, via the thermal device, to the one or more optical elements of the optical projection system, and one or more sections of at least one of the one or more optical elements with which the irradiance is to be applied.
45. The method of any one of clauses 43-44, wherein the steady state wavefront is determined by: computing a simulated wavefront drift due to the wavefront, wherein the wavefront drift is based on a difference between the wavefront and a target wavefront, the target wavefront data comprising the target wavefront; adjusting at least one of: the one or more operational settings of the thermal device or a configuration of the one or more optical elements of the optical projection system to minimize a cost function, the cost function estimating an edge placement error (EPE) cost for a given set of operation settings of the thermal device and a given configuration of the one or more optical elements of the optical projection system.
46. The method of clause 45, wherein minimizing the cost function comprises determining a first set of operational setting of the thermal device and a first configuration of the one or more optical elements of the optical projection system that produce a minimum EPE cost, based on the cost function.
47. The method of clause 46, wherein the operations further comprise adjusting the one or more operational settings of the thermal device to obtain the first set of operational settings for the thermal device and adjusting the configuration of the one or more optical elements of the optical projection system to obtain the first configuration of the one or more optical elements of the optical projection system.
48. The method of any one of clauses 41-47, wherein the wavefront is generated based on a wavefront generation model that takes, as input, a heating state induced by an illumination source of the semiconductor processing apparatus and a heating state induced by the thermal energy output by the thermal device to the optical projection system, wherein the wavefront generation model outputs a simulated wavefront based on the input heating state induced by the illumination source and the heating state induced by the thermal energy output by the thermal device.
49. The method of clause 48, wherein a configuration-based wavefront is generated based on a heating state induced by a configuration of one or more optical elements of the optical projection system, wherein a total wavefront, computed by summing the simulated wavefront and the configuration-based wavefront, is weighted using one or more semiconductor processing metrics to obtain a weighted wavefront.
50. The method of clause 49, wherein the one or more semiconductor processing metrics used to weight the total wavefront are lithography metrics.
51. The method of clause 50, wherein the wavefront drift is determined based on a difference between the weighted wavefront and a target wavefront, the target wavefront data comprising the target wavefront.
52. The method of clause 51, wherein determining the one or more process parameters comprises: determining first operational settings of the thermal device and a first configuration of the one or more optical elements of the optical projection system that reduce a magnitude of the wavefront drift.
53. The method of clause 52, wherein reducing the magnitude of the wavefront drift comprises reducing an error induced by the wavefront drift.
54. The method of any one of clauses 41-53, wherein the optical projection system comprises one or more optical elements, the wavefront data is further determined based on a configuration of the one or more optical elements.
55. The method of clause 54, wherein the configuration of the one or more optical elements of the optical projection system comprises an orientation of the one or more optical elements of the optical projection system.
56. The method of any one of clauses 54-55, wherein the configuration of the optical projection system comprises a material composition of each of the one or more optical elements.
57. The method of any one of clauses 41-56, wherein the optical projection system comprises one or more optical elements, each of the one or more optical elements has one or more degrees of freedom.
58. The method of clause 57, wherein an orientation of the one or more optical elements is adjusted along at least one of the one or more degrees of freedom via one or more control devices.
59. The method of any one of clauses 57-58, wherein the one or more degrees of freedom comprises six degrees of freedom.
60. The method of any one of clauses 54-59, wherein the one or more optical elements comprise six optical elements.
61. The method of clause 60, wherein each of the six optical elements is a reflective optical element.
62. The method of any one of clauses 54-61, wherein each of the one or more optical elements is a transmissive optical element.
63. The method of any one of clauses 41-62, wherein the one or more process parameters comprise a set of operational settings of the thermal device.
64. The method of clause 63, wherein the set of operational settings comprise an amount of irradiance output from the thermal device.
65. The method of any one of clauses 63-64, wherein the set of operation settings of the thermal device comprises one or more sections of the optical projection system with which the irradiance output by the thermal device is to be applied.
66. The method of any one of clauses 63-65, wherein determining the one or more process parameters comprises: determining an adjustment to one or more operational settings of the set of operational settings of the thermal device based on the wavefront data, the target wavefront data, and one or more semiconductor processing metrics.
67. The method of clause 66, wherein the operations further comprise: determining, based on the wavefront drift, an adjustment to a configuration of the optical projection system.
68. The method of clause 67, wherein the one or more semiconductor processing metrics are computed based on radiation output from an illumination source and the configuration of the optical projection system.
69. The method of any one of clauses 67-68, wherein the operations further comprise: obtaining first instructions indicating the adjustment to be made to the one or more operational settings of the thermal device and second instructions indicating the adjustment to be made to the configuration of the optical projection system.
70. The method of clause 69, wherein the operations further comprise: providing the first instructions to the thermal device; and providing the second instructions to one or more control devices, the one or more control devices being configured to adjust the configuration of the optical projection system.
71. The method of clause 70, wherein the first instructions and the second instructions are provided simultaneously.
72. The method of any one of clauses 41-71, wherein the one or more process parameters are determined to compensate for the wavefront drift.
73. The method of clause 72, wherein compensating for the wavefront drift comprises: determining an adjustment to the one or more process parameters associated with the thermal device; and determining an adjustment to a configuration of the optical projection system, wherein: the adjustment to the one or more process parameters associated with the thermal device and the adjustment to the configuration of the optical projection system are determined by minimizing a magnitude of the wavefront drift.
74. The method of clause 73, wherein minimizing the magnitude of the wavefront drift comprises: modifying the adjustment to the one or more process parameters associated with the thermal device and the adjustment to the configuration of the optical projection system until the wavefront drift satisfies a condition.
75. The method of clause 74, wherein the condition is satisfied responsive to determining, based on the wavefront data and the target wavefront data, that a difference between the wavefront and a target wavefront is less than a threshold wavefront drift value, wherein the target wavefront data comprises the target wavefront.
76. The method of any one of clauses 72-75, wherein compensating for the wavefront drift comprises minimizing an edge placement error (EPE) cost.
77. The method of clause 76, wherein minimizing the EPE cost comprises: determining an adjustment to the one or more process parameters associated with the thermal device and an adjustment to a configuration of the optical projection system that yields a minimum EPE cost.
78. The method of clause 70, wherein the operations further comprise: determining the minimum EPE cost, wherein determining the minimum EPE cost comprises modifying the adjustment to the one or more process parameters associated with the thermal device and the adjustment to the configuration of the optical projection system until the EPE cost satisfies a condition.
79. The method of clause 78, wherein the condition is satisfied responsive to determining that the EPE cost is less than a threshold EPE cost.
80. The method of any one of clauses 76-79, wherein minimizing the EPE cost comprises: determining EPE costs of a cost function for a set of variables, wherein the set of variables comprises a plurality of process parameters associated with the thermal device and a plurality of configurations of the optical projection system; selecting, from the EPE costs, a minimum EPE cost; and extracting, based on the minimum EPE cost, one or more process parameters from the plurality of process parameters associated with the thermal device and one or more configurations of the optical projection system that produce the minimum EPE cost.
81. The method of clause 80, wherein the cost function computes an edge placement error (EPE) cost.
82. The method of any one of clauses 41-81, wherein the optical projection system comprises one or more optical elements, the thermal device is configured to output irradiance based on the one or more process parameters that are determined, and the irradiance output by the thermal device is applied to at least one of the one or more optical elements.
83. The method of any one of clauses 41-82, wherein the operations further comprise: determining one or more additional process parameters associated with an additional thermal device, wherein the additional thermal device is configured to output irradiance based on the one or more additional process parameters that are determined, the irradiance output by the additional thermal device being applied to one or more optical elements of the optical projection system.
84. The method of any one of clauses 41-83, wherein the thermal device is configured to improve correction capability of the semiconductor processing apparatus or the optical projection system.
85. The method of any one of clauses 41-84, wherein the one or more process parameters are application layer specific.
86. The method of any one of clauses 41-85, wherein the thermal device providing the thermal energy comprises the thermal device providing heating or cooling to the optical projection system.
87. The method of any one of clauses 41-86, wherein the thermal device is a heating device or a cooling device.
88. The method of any one of clauses 41-87, wherein the thermal energy comprises irradiance.
89. A semiconductor processing apparatus, comprising: an optical projection system configured to provide a wavefront represented by wavefront data; and one or more thermal devices configured to provide thermal energy to the optical projection system during operation, wherein the thermal energy is determined based on one or more process parameters comprising parameters associated with the one or more thermal devices, wherein the one or more process parameters are determined based on wavefront drift, the wavefront drift being determined based on a comparison of the wavefront data and target wavefront data, wherein the semiconductor processing apparatus is configured to perform the method of any one of clauses 1-88.
90. A system, comprising: memory storing computer program instructions; and one or more computer processors configured to execute the computer program instructions to perform the method of any one of clauses 1-88.
91. A non-transitory computer-readable medium storing computer-readable instructions that, when executed, effectuate operations comprising the method of any one of clauses 1-88.

1. A non-transitory computer-readable medium storing computer program instructions that, when executed by one or more processors, are configured to cause the one or more processors to at least:
receive wavefront data representing a wavefront provided by an optical projection system of a semiconductor processing apparatus;
determine wavefront drift based on a comparison of the wavefront data and target wavefront data; and
determine, based on the wavefront drift, one or more process parameters, wherein the one or more process parameters comprises one or more parameters associated with a thermal device, wherein the thermal device is configured to provide thermal energy to the optical projection system during operation.

2. The non-transitory computer-readable medium of claim 1, wherein the optical projection system comprises one or more optical elements, wherein each of the one or more optical elements has one or more degrees of freedom, and one or more control devices are configured to adjust an orientation of the one or more optical elements along at least one of the one or more degrees of freedom of at least one of the one or more optical elements, and wherein each of the optical elements is a reflective or transmissive optical element.

3. The non-transitory computer-readable medium of claim 1, wherein the one or more process parameters comprises a set of operational settings of the thermal device, wherein the set of operational settings of the thermal device comprises an amount of irradiance output from the thermal device, and/or a location on an optical element where the irradiance output from the thermal device is to be applied.

4. The non-transitory computer-readable medium of claim 3, wherein the instructions configured to cause the one or more processors to determine the one or more process parameters are further configured to cause the one or more processors to determine an adjustment to one or more operational settings of the set of operational settings of the thermal device based on the wavefront data, the target wavefront data, and one or more semiconductor processing metrics.

5. The non-transitory computer-readable medium of claim 1, wherein the instructions are further configured to cause the one or more processors to determine, based on the wavefront drift, an adjustment to a configuration of the optical projection system.

6. The non-transitory computer-readable medium of claim 4, wherein the one or more semiconductor processing metrics are computed based on radiation output from an illumination source and a configuration of the optical projection system.

7. The non-transitory computer-readable medium of claim 6, wherein the instructions are further configured to cause the one or more processors to obtain first instructions indicating the adjustment to be made to the one or more operational settings of the thermal device and second instructions indicating the adjustment to be made to the configuration of the optical projection system.

8. The non-transitory computer-readable medium of claim 7, wherein the instructions are further configured to cause the one or more processors to:
provide the first instructions to the thermal device; and
provide the second instructions to one or more control devices, the one or more control devices being configured to adjust the configuration of the optical projection system.

9. The non-transitory computer-readable medium of claim 1, wherein the one or more process parameters are determined to compensate for the wavefront drift.

10. The non-transitory computer-readable medium of claim 9, wherein the instructions configured to cause the one or more processors to compensate for the wavefront drift are further configured to cause the one or more processors to:
determine an adjustment to the one or more process parameters associated with the thermal device; and
determine an adjustment to a configuration of the optical projection system,
wherein the adjustment to the one or more process parameters associated with the thermal device and the adjustment to the configuration of the optical projection system are determined based on a magnitude of the wavefront drift.

11. The non-transitory computer-readable medium of claim 9, wherein the instructions configured to cause the one or more processors to compensate for the wavefront drift are further configured to cause the one or more processors to do so based on an edge placement error (EPE) or a wavefront drift cost function.

12. The non-transitory computer-readable medium of claim 1, wherein the wavefront data is determined based on a heating state induced to one or more optical elements of the optical projection system by light output by an illumination source of the semiconductor processing apparatus and a heating state induced by the thermal device.

13. The non-transitory computer-readable medium of claim 12, wherein the heating state induced by the thermal device is determined based on the one or more process parameters associated with the thermal device, the one or more process parameters comprising operational settings of the thermal device.

14. The non-transitory computer-readable medium of claim 13, wherein the operational settings of the thermal device comprise a power level provided to the thermal device to cause the thermal device to output a prescribed amount of irradiance provided by the thermal device to the one or more optical elements of the optical projection system and one or more sections of at least one of the one or more optical elements with which the irradiance is to be applied.

15. The non-transitory computer-readable medium of claim 14, wherein the heating state induced to the one or more optical elements by the light output by the illumination source of the semiconductor processing apparatus is determined based on a wavefront, detected via a wavefront sensor, after a portion of a semiconductor fabrication process executed by the semiconductor processing apparatus has been performed.

16. The non-transitory computer-readable medium of claim 14, wherein the instructions are further configured to cause the one or more processors to determine one or more additional process parameters associated with an additional thermal device, wherein the additional thermal device is configured to output irradiance based on the one or more additional process parameters that are determined, the irradiance output by the additional thermal device being applied to the at least one of the one or more optical elements and/or at least another of the one or more optical elements.

17. The non-transitory computer-readable medium of claim 1, wherein the one or more process parameters are application layer specific.

18. A method comprising:
receiving wavefront data representing a wavefront provided by an optical projection system of a semiconductor processing apparatus;
determining wavefront drift based on a comparison of the wavefront data and target wavefront data; and
determining, by a hardware computer and based on the wavefront drift, one or more process parameters, wherein the one or more process parameters comprises one or more parameters associated with a thermal device, wherein the thermal device is configured to provide thermal energy to the optical projection system during operation.

19. The method of claim 18, wherein the one or more process parameters comprises a set of operational settings of the thermal device, wherein the set of operational settings of the thermal device comprises an amount of irradiance output from the thermal device, and/or a location on an optical element where the irradiance output from the thermal device is to be applied.

20. The method of claim 18, further comprising determining, based on the wavefront drift, an adjustment to a configuration of the optical projection system.
